(19) United States
(12) Patent Application Publication
(10) Pub. No.: US 2024/0114773 A1
(43) Pub. Date: Apr. 4, 2024

(54) SPIRO-OMETAD COMPRISING COMPOSITIONS, DEVICES COMPRISING THE SAME AND METHODS OF MAKING THE SAME

(71) Applicant: Georgia Tech Research Corporation, Atlanta, GA (US)

(72) Inventors: Juan-Pablo Correa-Baena, Atlanta, GA (US); Mark D. Losego, Atlanta, GA (US); Andres-Felipe Castro-Mendez, Atlanta, GA (US); Selma Fairach, Atlanta, GA (US); Emily K. McGuinness, Atlanta, GA (US); Carlo Andrea Riccardo Perini, Atlanta, GA (US); Jamie P. Wooding, Atlanta, GA (US)

(21) Appl. No.: 18/237,037

(22) Filed: Aug. 23, 2023

Related U.S. Application Data
(60) Provisional application No. 63/400,102, filed on Aug. 23, 2022.

(51) Int. Cl. H10K 85/60; H10K 30/40; H10K 85/50

(52) U.S. Cl. CPC H10K 85/633; H10K 30/40; H10K 85/50; H10K 30/84; H10K 85/624

(57) ABSTRACT

The present disclosure provides for a composition comprising a compound configured to form internal π bonds, and an inorganic material, wherein the composition is defined by a first surface opposing a second surface and a first thickness measured from the first surface to the second surface of the composition, and a method of making thereof. Further provided herein is a device comprising at least one of the compositions disclosed herein. Also disclosed herein is a photovoltaic device.

### CROSS-REFERENCE TO RELATED APPLICATIONS

This application claims the benefit of priority to, and the benefit of, U.S. Provisional Application No. 63/400,102 filed on Aug. 23, 2022, the disclosure of which is hereby expressly incorporated by reference herein in its entirety.

### STATEMENT OF GOVERNMENT SUPPORT

This invention was made with government support under Grant No. DE-EE0009369, awarded by the Department of Energy. The government has certain rights in the invention.

### BACKGROUND

The shortage of fossil fuel reserves has been a common problem faced by mankind Harvesting solar energy has been one response to this shortage, particularly through the use of devices such as perovskite solar cells (PSCs). Stability is still a major roadblock for the commercialization of these devices. For example, the long-term stability of devices using Spiro-OMeTAD is low despite the high photoelectric conversion efficiency (PCE). PSCs are easily degraded by water and heat, which is an issue in organic hole-transport layers (HTLs) and has an irreversible effect on the decomposition of perovskites. In addition, using an organic HTL to manufacture PSCs has further obstacles, such as the cost of materials.

The composition and methods disclosed herein address these and other needs.

### SUMMARY

In accordance with the purposes of the disclosed materials and methods, as embodied and broadly described herein, the disclosed subject matter, in one aspect, relates to a composition and methods related thereto.

Thus, in one example, a composition is provided, including a compound configured to form internal π bonds and an inorganic material, wherein the composition is defined by a first surface opposing a second surface and a first thickness measured from the first surface to the second surface of the composition.

In a further example, a device comprising at least one of the compositions disclosed herein is provided.

Additionally, a photovoltaic device is provided, comprising: a perovskite material layer; and a layer comprising a composition comprising a compound and an inorganic material, wherein the layer is defined by a first surface opposing a second surface and a first thickness measured from the first surface to the second surface; wherein the second surface overlays the perovskite material layer, wherein the compound comprises a Spiro-OMeTAD.

Further provided herein is a method of making the composition disclosed herein, including exposing a layer of the compound to a vapor phase comprising a first precursor for a first predetermined time, thereby at least partially adsorbing at least a portion of the first precursor on a surface of the layer and/or at least partially infiltrating the layer of the compound with at least a portion of the first precursor to form a modified compound; and exposing the modified compound to a second precursor for a second predetermined time, thereby reacting the first precursor with the second precursor to form an inorganic material, thereby forming the composition comprising a first portion of the inorganic material dispersed within the layer of the compound and a second portion of the inorganic material at least partially disposed on the surface of the layer.

Additional advantages will be set forth in part in the description that follows, and in part will be obvious from the description or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

### BRIEF DESCRIPTION OF THE DRAWINGS

The accompanying figures, which are incorporated in and constitute a part of this specification, illustrate several aspects described below.

FIGS. 1A and 1B show vapor phase infiltration (VPI) of Spiro-OMeTAD. FIG. 1A shows a schematic of the process: expose to a low-pressure TiCl₄ vapor, purge reaction chamber, expose to a low-pressure water vapor, and purge the chamber. FIG. 1B shows a depiction of chemical mechanisms during infiltration: sorption of the TiCl₄ precursor, diffusion into the Spiro-OMeTAD, possible binding of the Spiro-OMeTAD, and eventual reaction with the subsequent water co-reactant to form nonvolatile inorganic clusters.

FIG. 2 shows a schematic of an example TiCl₄ VPI process vs. a thermal control process on a device stack with a processing temperature of 70° C.

FIGS. 3A-3C show characterization of an example Spiro-OMeTAD layer as a function of infiltration time. FIG. 3A shows XPS Ti 2p peak area vs. etch depth (nm). FIG. 3B shows UV-vis. absorption spectra and Tauc plots. FIG. 3C shows XRD scans indicating the characteristic peaks for α-FAPbI₃, δ-FAPbI₃ and PbI₂.

FIGS. 4A-4F show electrical characterization of example PSCs containing hybrid TiOₓ:Spiro-OMETAD layers. FIG. 4A shows the device architecture. FIG. 4B shows the electrical characterization of JSC. FIG. 4C shows the electrical characterization of Voc. FIG. 4D shows the electrical characterization of fill factor (FF). FIG. 4E shows the electrical characterization of power conversion efficiency (PCE) obtained from reverse J-V curves. FIG. 4F shows the electrical characterization of stabilized PCE taken with 1 minute of maximum power point tracking (MPPT).

FIGS. 5A-5C show an electrical characterization of thermal control. FIG. 5A shows stabilized PCE of thermal control with varying time. FIG. 5B shows a J-V curve of champion pixel of an example device that underwent a thermal control process of 10 h. FIG. 5C shows a J-V curve of champion pixel of an example device using 10 h TiCl₄ exposure time.

FIGS. 6A-6C show optoelectronic properties of the infiltrated Spiro-OMeTAD. FIG. 6A shows UV-VIS absorption spectra and Tauc plot. FIG. 6B shows UPS spectra, wherein the left graph is a zoom-in on the position of the work function, and the right graph is a zoom-in on the position of the valence band maxima. FIG. 6C shows an XPS Valence band scan.

FIGS. 7A-7C show stability test under different conditions. FIG. 7A shows shelf storage at 20° C. under N₂ and dark. FIG. 7B shows stress at 85° C. and illumination. FIG. 7C shows an operando stability test at 75° C.

FIGS. 8A-8E show characterization of Spiro-OMeTAD and devices after degradation.

FIG. 8A shows UV-VIS absorption spectra. FIG. 8B shows XRD patterns of the circular average of GIWAXS patterns of the Spiro-OMeTAD layer with varying VPI exposure time. FIG. 8C shows the characterization of an incident angle of 0.05° (most surface sensitive). FIG. 8D shows the characterization of an incident angle of 0.10. FIG. 8E shows the characterization of an incident angle of 0.50 (most bulk sensitive).

FIGS. 9A-9E show VPI chamber pressure profiles for 1-hour TiCl₄ exposure (FIG. 9A), 3-hour TiCl₄ exposure (FIG. 9B), 5-hour TiCl₄ exposure (FIG. 9C), 10-hour TiCl₄ exposure (FIG. 9D), and 10-hour thermal control with no TiCl₄ exposure (FIG. 9E).

FIGS. 10A-10C show a complete XPS depth profile for each device stack, including Au4f, C1s, O1s, Ti2p, and I3d for the reference, which had no VPI (FIG. 10A), 3 h TiCl₄ exposure (FIG. 10B), and 10 h TiCl₄ exposure (FIG. 10C).

FIGS. 11A-11B show an in situ normalized mass change of Spiro-OMeTAD during vapor phase infiltration with TiCl₄ and water vapor as measured by quartz crystal microbalance (QCM) gravimetry (FIG. 11A) and accompanying recorded chamber pressure profile during QCM data collection, with each step of the VPI process noted (FIG. 11B).

FIG. 12 shows ex situ FTIR of hybrid TiOₓ: Spiro-OMeTAD on a QCM crystal following infiltration at 70° C. with TiCl₄ and water vapor and neat Spiro-OMeTAD FTIR.

FIGS. 13A-13F show surface chemistry composition as measured by XPS survey scans. FIG. 13A shows the surface chemistry of reference Spiro-OMeTAD (VPO14). FIG. 13B shows the surface chemistry of reference Spiro-OMeTAD (VB5). FIG. 13C shows the surface chemistry of thermal control Spiro-OMeTAD. FIG. 13D shows the surface chemistry of hybrid TiOₓ/Spiro-OMeTAD (1 hr. TiCl₄ 70° C.). FIG. 13E shows the surface chemistry of hybrid TiOₓ/Spiro-OMeTAD (3 hr. TiCl₄ 70° C.). FIG. 13F shows the surface chemistry of hybrid TiOₓ/Spiro-OMeTAD (10 hr. TiCl₄ 70° C.).

FIGS. 14A-14F show the surface chemistry analysis via deconvoluted XPS core level spectra of C1s, O1s, and N1s. FIG. 14A shows the surface chemistry of reference Spiro-OMeTAD (VPO14). FIG. 14B shows the surface chemistry of reference Spiro-OMeTAD (VB5). FIG. 14C shows the surface chemistry of thermal control Spiro-OMeTAD. FIG. 14D shows the surface chemistry of hybrid TiOₓ/Spiro-OMeTAD (1 hr. TiCl₄ 70° C.). FIG. 14E shows the surface chemistry of hybrid TiOₓ/Spiro-OMeTAD (3 hr. TiCl₄ 70° C.). FIG. 14F shows the surface chemistry of hybrid TiOₓ/Spiro-OMeTAD (10 hr. TiCl₄ 70° C.).

FIG. 15 shows an XRD scan of complete devices after VPI indicating the characteristic peaks for α-FAPbI₃, δ-FAPbI₃, PbI₂, and Au.

FIG. 16 shows a UV-VIS of the FTOlC-TiO₂|PVK|Spiro-OMeTAD films before and after infiltration.

FIGS. 17A-17D show J-V curves of champion pixels of PSCs with PEAI passivation and hybrid TiOₓ:Spiro-OMeTAD. FIG. 17A shows the J-V curve for a reference material. FIG. 17B shows a J-V curve for TiCl₄ at 70° C. for 3 hours. FIG. 17C shows a J-V curve for TiCl₄ at 70° C. for 5 hours. FIG. 17D shows aa J-V curve for TiCl₄ at 70° C. for 10 hours.

FIGS. 18A-18C show J-V curves of champion pixels of PSCs with PEAI passivation and thermal control Spiro-OMeTAD. FIG. 18A shows a J-V curve for a reference material. FIG. 18B shows a J-V curve for a material with no TiCl₄, at 70° C. at 5 hours. FIG. 18C shows a J-V curve for a material with no TiCl₄, at 70° C. at 10 hours.

FIGS. 19A-19D show an electrical characterization of PSCs with PEAI passivation and thermal control Spiro-OMeTAD. FIG. 19A shows a short circuit density of current (J_{sc}). FIG. 19B shows an open circuit voltage (V_{OC}). FIG. 19C shows fill factor FF. FIG. 19D shows a power conversion efficiency (PCE) taken from reverse JV curves.

FIGS. 20A-20C show ultraviolet photoelectron spectroscopy (UPS) of SilSpiro-OMeTAD films with varying conditions—binding energy of 0-15 eV (FIG. 20A), the binding energy of 15-18 eV (FIG. 20B), and binding energy of 0-5 eV (FIG. 20C).

FIG. 21 shows an XPS valence scan of SilSpiro-OMeTAD films with varying conditions.

FIG. 22 shows XRD of complete devices (FTO|c-TiO2|mp-TiO2|PEAI|PVK|PEAI|Spiro-OMeTAD|Au) after stressing at 85° C. for 48 h.

FIG. 23 shows the chemical structure of Spiro-OMeTAD.

FIG. 24 shows the π-π stacking of Spiro-OMeTAD.

FIGS. 25A-25C show XPS depth profiles of TIOₓ infiltration. FIG. 25A shows the etch depth for untreated Spiro-OMeTAD. FIG. 25B shows the etch depth for Spiro-OMeTAD after 3 hrs. of exposure to TiCl₄. FIG. 25C shows the etch depth for Spiro-OMeTAD after 10 hrs. of TiCl₄ exposure.

FIG. 26 shows the glass transition temperature of neat Spiro-OMeTAD.

FIG. 27A-27C show the glass transition temperature of TiOₓ-Spiro hybrids. FIG. 27A shows the glass transition temperature for neat Spiro-OMeTAD. FIG. 27B shows the glass transition temperature of Spiro-OMeTAD after exposure to TiCl₄ after 3 hrs. at 70° C. FIG. 27C shows the glass transition temperature of Spiro-OMeTAD after exposure to TiCl₄ after 10 hrs. at 70° C.

FIGS. 28A-28B show C is XPS analysis of infiltrated Spiro-OMeTAD. FIG. 28A shows the binding energy of untreated Spiro-OMeTAD. FIG. 28B shows the binding energy of Spiro-OMeTAD after 10 hrs. of exposure to TiCl₄.

FIG. 29 shows the disruption of π-π stacking with VPI inorganics.

FIG. 30 shows long-term stability of unsealed devices based on three HTLs stored in 20° C. under ambient humidity of 50%-80%. The water contact angle was measured as supplementary evidence.

### DETAILED DESCRIPTION

The following description of the disclosure is provided as an enabling teaching of the disclosure in its best, currently known embodiments. Many modifications and other embodiments disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As can be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It can be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### Definitions

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by,” “comprising,” “comprises,” “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.”

As used in the specification and the appended claims, the singular forms “a,” “an,” and “the” include plural referents unless the context clearly dictates otherwise. Thus, for example, reference to “a compound,” “a composition,” or “a solar cell” includes, but is not limited to, two or more such compounds, compositions, or solar cells, and the like.

It should be noted that ratios, concentrations, amounts, and other numerical data can be expressed herein in a range format. It can be further understood that the endpoints of each of the ranges are significant both in relation to the other endpoint and independently of the other endpoint. It is also understood that there are a number of values disclosed herein and that each value is also herein disclosed as “about” that particular value in addition to the value itself. For example, if the value “10” is disclosed, then “about 10” is also disclosed. Ranges can be expressed herein as from “about” one particular value and/or to “about” another particular value. Similarly, when values are expressed as approximations, by use of the antecedent “about,” it can be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g., the phrase “x to y” includes the range from ‘x’ to ‘y’ as well as the range greater than ‘x’ and less than ‘y’. The range can also be expressed as an upper limit, e.g., ‘about x, y, z, or less’ and should be interpreted to include the specific ranges of ‘about x,’ ‘about y’, and ‘about z’ as well as the ranges of ‘less than x,’ ‘less than y’, and ‘less than z.’ Likewise, the phrase ‘about x, y, z, or greater’ should be interpreted to include the specific ranges of ‘about x,’ ‘about y’, and ‘about z’ as well as the ranges of ‘greater than x,’ greater than y’, and ‘greater than z.’ In addition, the phrase “about ‘x’ to ‘y’,” where ‘x’ and ‘y’ are numerical values, includes “about ‘x’ to about ‘y’.”

It is to be understood that such a range format is used for convenience and brevity and, thus, should be interpreted in a flexible manner to include not only the numerical values explicitly recited as the limits of the range but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5% but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself unless specifically stated otherwise. As used herein, the term “substantially free,” when used in the context of a composition or component of a composition that is substantially absent, is intended to refer to an amount that is then about 1% by weight or less, e.g., less than about 0.5% by weight, less than about 0.1% by weight, less than about 0.05% by weight, or less than about 0.01% by weight of the stated material, based on the total weight of the composition.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”).

It will be understood that although the terms “first,” “second,” etc., may be used herein to describe various elements, components, regions, layers, and/or sections. These elements, components, regions, layers, and/or sections should not be limited by these terms. These terms are only used to distinguish one element, component, region, layer, or section from another element, component, region, layer, or a section. Thus, a first element, component, region, layer, or section discussed below could be termed a second element, component, region, layer, or section without departing from the teachings of exemplary aspects.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein are interpreted accordingly.

### Composition

### Composition

Provided herein is a composition comprising a compound configured to form internal π bonds and an inorganic material, wherein the composition is defined by a first surface opposing a second surface and a first thickness measured from the first surface to the second surface of the composition. A π bond refers to the overlap of p orbitals on adjacent atoms, perpendicular to any sigma bond(s) between the same atoms. In some examples, the internal π bonds comprise π-π stacking. π-π stacking refers to the noncovalent π interactions (orbital overlap) between the π bonds of aromatic rings.

In further examples, the compound is a charge transport material. A charge transport material is configured to allow the flow of electrons to move from an interface while blocking holes. In some examples, the charge transport material acts as the anode when used in a device, such as a photovoltaic device. In certain examples, the charge transport material is a hole transport material. A hole transport material, also referred to as an anode interfacial layer, facilitates hole extraction and transportation while blocking electron flux. In some examples, hole transport materials include Spiro-OMeTAD and poly[bis(4-phenyl)(2,4,6-trimethylphenyl)amine (PTAA).

In specific examples, the compound comprises an organic triphenylamine-based molecule. Triphenylamine is an organic compound with formula (C₆H₅)₃N and has the below structure.

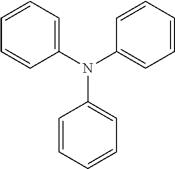 [SMILES: c1ccc(N(c2ccccc2)c2ccccc2)cc1]

In some examples, the organic triphenylamine-based molecule comprises Spiro-OMeTAD. Spiro-OMeTAD, also referred to as 2,2′,7,7′-Tetrakis[N,N-di(4-methoxyphenyl)amino]-9,9′-Spirobifluorene, is a hole transport material with the chemical formula C₈₁H₆₈N₄O₈ and the structure below.

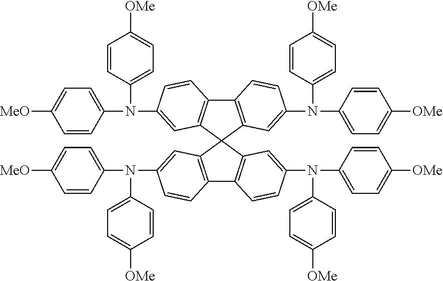 [SMILES: COc1ccc(N(c2ccc(OC)cc2)c2ccc3c(c2)C2(c4cc(N(c5ccc(OC)cc5)c5ccc(OC)cc5)ccc4-3)c3cc(N(c4ccc(OC)cc4)c4ccc(OC)cc4)ccc3-c3ccc(N(c4ccc(OC)cc4)c4ccc(OC)cc4)cc32)cc1]

Yet in other aspects, the organic triphenylamine-based molecule can comprise triphenylamine-quinoxaline-based (QC-TPA and QC-TPAOME) small organic molecules, poly(3,4-ethylenedioxythiophene):poly(styrene sulfonate) (PEDOT:PSS). TPI, TPI-2MEO, TPI-4MEO, TPI-6MEO

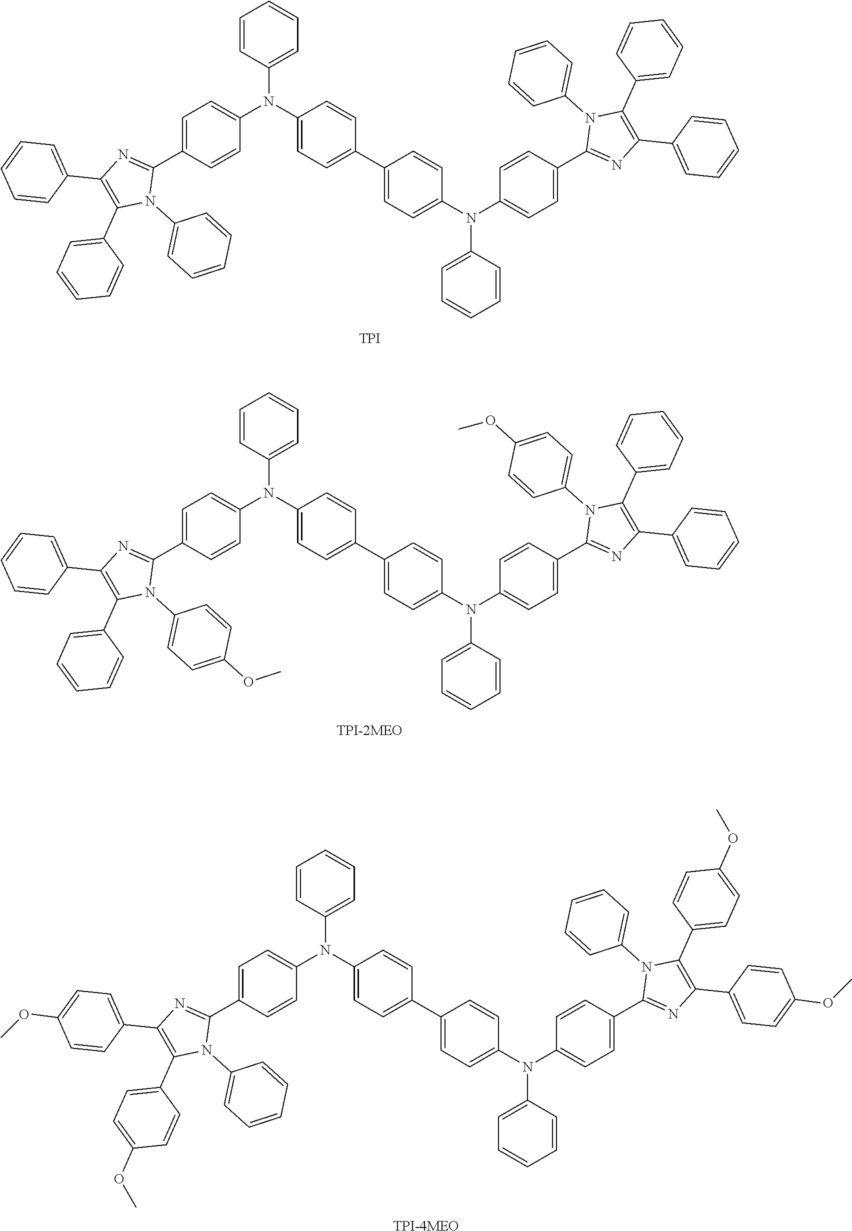

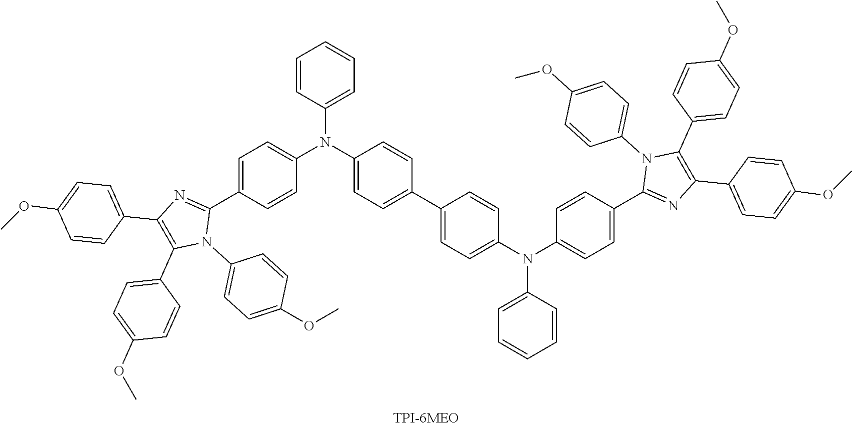

In further examples, the inorganic material is at least partially insulating. Insulating refers to the ability of a material to stop heat or electricity from escaping or entering. In certain examples, the inorganic material comprises a metal oxide, a metalloid oxide, a metal hydroxide, a metal oxyhydroxide, a ceramic material, or any combination thereof. In some examples, metal oxide includes Na₂O, MgO, CaO, SrO, BaO, Li₂O, Ag₂O, FeO, Fe₂O₃, CrO₃, TiO₂, ZrO₂, V₂O₅, MnO₄, Co₂O₃, NiO, Ni₂O₃, MoO₂, Nb₂O₅, Ta₂O₅, HfO₂, Yb₂O₃, La₂O₃, CeO₄, SnO₂, Cu₂O, CuO, ZnO, or any combination thereof and the like. In further examples, metalloid oxide includes BₓO_{y}, SiO₂, GeO₂, AsₓO_{y}, SbₓO_{y}, TeOₓ, or any combination thereof and the like. In certain examples, metal hydroxides include aluminum hydroxide, beryllium hydroxide, cobalt (II) hydroxide, copper (II) hydroxide, curium hydroxide, gold (III) hydroxide, iron (II) hydroxide, mercury (II) hydroxide, nickel (II) hydroxide, tin (II) hydroxide, uranyl hydroxide, zinc hydroxide, zirconium (IV) hydroxide, lithium hydroxide, rubidium hydroxide, cesium hydroxide, sodium hydroxide, potassium hydroxide, or any combination thereof and the like. In some exemplary and unlimiting aspects, metal oxyhydroxides include ZrO(OH)₂, FeOOH, TiO(OH)₂, or any combination thereof. In some examples, ceramic materials can include an inorganic, non-metallic oxide, nitride, carbide materials, or any combination thereof and the like. In such unlimiting examples, it can include aluminum oxide, aluminum nitride, syconium silicate, boron nitride, beryllium oxide, silicon, silicon carbide, M′₁₋ₓM″ₓTaO₄-based ceramics, any combination thereof and the like. In such aspects, M′₁₋ₓM″ₓTaO₄-based ceramics can comprise M′ and M″ selected from Al, Y, La, Pr, Eu, Cd, Tb, Sm, Yb, or any combination thereof.

In certain examples, a first portion of the inorganic material is dispersed within the first surface and within at least a portion of the first thickness of the composition. In some examples, the first portion of the inorganic material is disposed within a second thickness measured from the first surface, wherein the second thickness is smaller than the first thickness.

In certain aspects, the first thickness is 80 nm to 5 microns, including exemplary aspects of 100 nm, 120 nm, 150 nm, 200 nm, 300 nm, 400 nm, 500 nm, 600 nm, 700 nm, 800 nm, 900 nm, 1 micron, 2 microns, 3 microns, and 4 microns.

In some examples, the second thickness is from 20 nm to 60 nm. In some examples, the second thickness is from 20 nm to 30 nm, 30 nm to 40 nm, 40 nm to 50 nm, or 50 nm to 60 nm. In further examples, the second thickness is from 20 nm to 25 nm, 25 nm to 30 nm, 30 nm to 35 nm, 35 nm to 40 nm, 40 nm to 45 nm, 45 nm to 50 nm, 50 nm to 55 nm, or 55 nm to 60 nm. In certain examples, the second thickness is from 20 nm to 40 nm or 20 nm to 50 nm. In specific examples, the second thickness is from 10 nm to 35 nm, 25 nm to 45 nm, or 25 nm to 55 nm. In some examples, the second thickness is at least 20 nm, at least 30 nm, at least 40 nm, at least 50 nm, or at least 60 nm. In further examples, the second thickness is at least 25 mm, at least 35 nm, at least 45 nm, or at least 55 nm.

In certain examples, a second portion of the inorganic material is disposed on the first surface. In specific examples, at least a portion of the inorganic material is present as one or more clusters. A cluster refers to a collection of more than one atom (e.g., 10, 20, 30, 40, 50, 100, 200, 400, 500 atoms) with an average characteristic dimension (e.g., diameter) of 0.5 nm to 100 nm.

In some examples, the inorganic material comprises one or more of Al_{y}Oₓ, SiOₓ, HfOₓ, ZrOₓ, Ta_{y}Oₓ, Y_{y}Oₓ, Ir_{y}Oₓ, RuOₓ, WOₓ, Ni_{y}Oₓ, TiOₓ, InOₓ, NiOₓ, ZnOₓ, CuOₓ, V_{y}O_{z}, Al_{y}OₓH_{z}, SiOₓH_{z}, HfOₓH_{z}, ZrOₓH_{z}, Ta_{y}OₓH_{z}, Y_{y}OₓH_{z}, Ir_{y}OₓH_{z}, RuOₓH_{z}, WOₓH_{z}, Ni_{y}OₓH_{z}, TiOₓH_{z}, InOₓH_{z}, NiOₓH_{z}, ZnOₓH_{z}, CuOₓH_{z}, V_{y}O_{z}H_{z}, or a combination thereof.

In certain examples, the inorganic material is unbound to the compound. As used herein, unbound refers to two materials being unattached to one another via any primary chemical bonds. In further examples, the inorganic material is bound to the compound via secondary bonds, such as van Der Waals bonds. In some unlimiting examples, the composition is substantially stable. In such examples, the composition does not degrade at a temperature from room temperature to 85° C., including exemplary values of 25° C., 30° C., 35° C., 40° C., 45° C., 50° C., 55° C., 60° C., 65° C., 70° C., and 80° C. Stable refers to the ability of a composition to resist a change or decomposition via external factors.

In some examples, the composition is substantially free of crystalline phase at a temperature of 60° C. to 85° C. In further examples, the composition is substantially free of crystalline phase at a temperature of 60° C. to 65° C., 65° C. to 70° C., 70° C. to 75° C., 75° C. to 80° C., or 80° C. to 85° C. In certain examples, the composition is substantially free of crystalline phase at a temperature of 60° C. to 70° C. or 60° C. to 80° C. In specific examples, the composition is substantially free of crystalline phase at a temperature of at least 60° C., at least 65° C., at least 70° C., at least 75° C., or at least 80° C.

In further examples, the inorganic material can have any form or shape suitable for the desired application. For example and without limitations, the inorganic material can be present as a nanosheet, a nanoparticle, a nanowire, or any combination thereof. A nanosheet refers to a two-dimensional array of atoms or molecules in a single layer or multiple layers. It is understood that the nanosheet does not have predetermined dimensions, and the material can be present as nanoflakes, nanofilms, and the like. A nanoparticle is a particle of matter having an average characteristic dimension (e.g., diameter) of from 1 nm to 900 nm, including exemplary values of 5 nm, 10 nm, 20 nm, 30 nm, 40 nm, 50 nm, 60 nm, 70 nm, 80 nm, 90 nm, 100 nm, 125 nm, 150 nm, 175 nm, 200 nm, 250 nm, 300 nm, 400 nm, 500 nm, 600 nm, 700 nm, and 800 nm. In some examples, the nanoparticles can be substantially spherical. Yet is other examples, the nanoparticle can have any regular or irregular form. For example, and without limitations, the nanoparticles can be substantially oval, cubic, prism, helical, or pillar shape.

In further examples, the nanoparticles can have a high surface area-to-volume ratio. In such aspects, the nanoparticles can be present as nanotubes, nanowires, nanofibers, and the like. A nanowire is a nanostructure in the form of a wire with an average characteristic dimension (e.g., diameter) of from 1 nm to 900 nm, including exemplary values of 5 nm, 10 nm, 20 nm, 30 nm, 40 nm, 50 nm, 60 nm, 70 nm, 80 nm, 90 nm, 100 nm, 125 nm, 150 nm, 175 nm, 200 nm, 250 nm, 300 nm, 400 nm, 500 nm, 600 nm, 700 nm, and 800 nm.

In certain examples, the compound comprises Spiro-OMeTAD, and the inorganic material comprises TiO₂. In some examples, at least a portion of the π-π stacking is disrupted. It is understood that the disruption of π-π stacking can cause a reduction in the occurrences of interactions between the π bonds of aromatic rings. In aspects disclosed herein, the inorganic material can cause the disruption of π-π stacking.

In some examples, the composition is formed by a vapor phase infiltration (VPI). VPI is a hybridization route that facilitates the incorporation of inorganic materials into an organic matrix, such as a polymeric matrix. In some examples, VPI allows for uniform incorporation of inorganic materials into the organic matrix.

### Device

Further provided herein is a device comprising at least one composition as disclosed herein. In some examples, the device is a photovoltaic cell.

Also provided herein is a photovoltaic device comprising a perovskite material layer; and a layer comprising a composition comprising a compound and an inorganic material, wherein the layer is defined by a first surface opposing a second surface and a first thickness measured from the first surface to the second surface; wherein the second surface overlays the perovskite material layer, wherein the compound comprises an organic triphenylamine-based molecule, further wherein the organic triphenylamine-based molecules comprises Spiro-OMeTAD. It is understood, however, that any of the mentioned above triphenylamine-based molecules can be used as a charge transfer.

In still further aspects, the device can further comprise one or more transparent layers. Any known in the art of photovoltaic devices transparent layers can be used. In certain exemplary and unlimiting aspects, the transparent layer can also be conductive. In certain exemplary and unlimiting aspects, the transparent layer can comprise indium tin oxide (ITO), glass, fluoride-doped tin oxides (FTO), gallium, doped zinc oxide glass, and niobium-doped titanium oxide glass, ZnO, conductive polymers, indium doped zinc oxide (IZO), or aluminum-doped zinc oxide (AZO), and the like.

In still further aspects, the device can comprise one or more blocking layers. Any known in the art photovoltaic cells blocking layers can be used. In certain aspects, a blocking layer can be positioned between a perovskite layer and the cathode layer to inhibit electron recombination. For example and without limitations, a blocking layer can comprise TiO₂, SnO₂, ZnO, CuO, NiO, or any combination thereof.

In still further aspects, the devices can comprise any additional layers commonly present in the photovoltaic device. For example, and without limitations, the device can comprise an electron transport layer and/or a hole transport layer.

In further examples, the electron transport layer tunes the crystallinity of the corresponding perovskite layer for improved device performance. Examples of materials used in electron transport layers include SnO₂, KOH, TiO₂, MgO, Al₂O₃, SnO₂, 1-benzyl-3-methylimidazolium, NiO₂, MoOₓ, VOₓ, and 1-butyl-3-methylimidazolium, for example. In still further aspects, the electron transport layer can comprise a mesoporous SnO₂, KOH, TiO₂, MgO, Al₂O₃, SnO₂, 1-benzyl-3-methylimidazolium, NiO₂, MoOₓ, VOₓ, or 1-butyl-3-methylimidazolium.

In still further aspects, the perovskite materials used in this disclosure can comprise any known in the art perovskite materials. In some aspects, the perovskite material has a general formula ABX₃, wherein A is one or more monovalent cations, B is one or more divalent inorganic cations, and X is one or more halide anions. In still further aspects, X can comprise one or more halide anions selected from fluoride, chloride, bromide, and iodide. In still further aspects, X can comprise two different halide anions selected from fluoride, chloride, bromide, and iodide. In still further aspects, A can comprise one or more organic cations selected from methylammonium (MA), formamidinium (FA), and ethyl ammonium (EA). Yet in still further aspects. A can comprise one or more inorganic cations selected from Cs⁺, Rb⁺, Cu⁺, Pd⁺, Pt⁺, Ag⁺, Au⁺, Rh⁺, and Ru⁺. In still further aspects, B can comprise at least one divalent inorganic cation selected from Pb²⁺ and Sn²⁺. In still further exemplary and unlimiting aspects, the perovskite material can be CsₓFA_{y}MA_{z}Pb(IₐBr_{b})₃, CsₓFA_{y}MA_{z}Sn(IₐBr_{b})₃, CsₓFA_{y}MA_{z}Ge(IₐBr_{b})₃, or any combination thereof. In such exemplary aspects, 0≤x≤1, 0≤y≤1, 0≤z≤1, 0≤a≤1, and 0≤b≤1. In further and unlimiting aspects, the bromide in the perovskite material can be at least partially substituted with fluoride, chloride, or iodide, for example.

In still further aspects, the device can comprise a passivation layer. In such exemplary and unlimiting aspects, the passivation layer can be disposed between the disclosed herein composition and the layer of the perovskite material. In some exemplary and unlimiting aspects, the passivation layer can comprise phenylethylammonium iodide, octylammonium iodide, butylammonium iodide, anthracene, 4-fluorobenzamide, D-4-tert-butylphenylalamine, tetrabutylammonium hexafluorophosphate, formamidinium bromide, iodopentafluorobenzene, fullerene, theophylline, 4-dimethylaminebenzoic acid, tribenzylphosphine oxide, 2-cyanoacrylate, pyridine, Zn porphyrin, Co porphyrin, Ni porphyrin, Cu porphyrin, H porphyrin, 4-tert-butyl-benzylammonium iodide, azetidinium iodide, o-(phenylene)di(ethylammonium) iodide, phenethylamine hydroiodate, benzylamine, n-butylamine hydroiodate, dioctylamine iodide, octylamine, phenethylamine, n-butlamine, ethylamine, or any combination thereof.

In still further aspects, the device can comprise a stack of lavers in the following order: a transparent layer; a charge transport layer (electrons or holes), a perovskite material layer, and another charge transport layer (electrons or holes), where the hole transport layer comprises the disclosed herein composition.

In still further aspects, the device is configured to retain from 60% to 90%, including exemplary values of 65%, 70%, 75%, 80%, and 85% of its initial efficiency after a stability test at a temperature range of 60° C. to 75° C., including exemplary values of 61° C., 62° C., 63° C., 64° C., 65° C., 66° C. 67° C. 68° C. 69° C., 70° C., 71° C., 72° C., 73° C., and 74° C. In still further aspects, this efficiency is retained for 4-0 to 100 h, including exemplary values of 50 h, 60 h, 70 h, 70 h, 80 h, and 90 h. In yet still further aspects, the stability test comprises illumination of the device.

### Method

### Method of Making the Composition

The present disclosure, in one aspect, provides for a method of making the disclosed herein compositions. In such aspects, the method comprises exposing a layer of the compound to a vapor phase comprising a first precursor for a first predetermined time, thereby at least partially adsorbing at least a portion of the first precursor on a surface of the layer and/or at least partially infiltrating the layer of the compound with at least a portion of the first precursor to form a modified compound; and exposing the modified compound to a second precursor for a second predetermined time, thereby reacting the first precursor with the second precursor to form an inorganic material, thereby forming the composition comprising a first portion of the inorganic material dispersed within the layer of the compound and a second portion of the inorganic material at least partially disposed on the surface of the layer.

In some examples, the first precursor comprises a metal salt, a metal-organic, an organometallic, or any combination thereof. In some examples, the first precursor comprises a metal salt selected from a salt of Sn, Al, Ti, In, Cu, Zn, Ni, V, or any combination thereof. In further examples, the second precursor is water vapor, oxygen gas, ozone, hydrogen peroxide, or any combination thereof.

### Method of Making a Photovoltaic Cell

Further provided herein is a method of making a photovoltaic cell, wherein the method comprises disposing the composition herein on a layer of a perovskite material. Also provided herein is a method of forming the photovoltaic device comprises providing a stack of layers, wherein at least one of the layers in the stack comprises a polymer, exposing the polymer to a vapor phase comprising a first precursor for a first predetermined amount of time, thereby at least partially adsorbing at least a portion of the first precursor on a surface of the layer and/or at least partially infiltrating the layer of the polymer with at least a portion of the first precursor to form a modified polymer layer; and exposing the modified polymer layer to a second precursor for a second predetermined time, thereby reacting the first precursor with the second precursor to form an inorganic material, thereby forming the polymer layer comprising a first portion of the inorganic material dispersed within the polymer layer and a second portion of the inorganic material at least partially disposed on the surface of the polymer layer. In some examples, exposing the polymer and/or exposing the modified polymer can substantially affect any of the layers in the stack.

In some examples, the first predetermined time is from 1 minute to 72 hours. In further examples, the first predetermined time is from 1 minute to 1 hour, 1 hour to 5 hours, 5 hours to 10 hours, 10 hours to 15 hours, 15 hours to 20 hours, 20 hours to 25 hours, 25 hours to 30 hours, 30 hours to 35 hours, 35 hours to 40 hours, 40 hours to 45 hours, 45 hours to 50 hours, 50 hours to 55 hours, 55 hours to 60 hours, 60 hours to 65 hours, 65 hours to 70 hours, or 70 hours to 75 hours. In certain examples, the first predetermined time is from 1 hour to 5 hours, 1 hour to 10 hours, 1 hour to 15 hours, 1 hour to 20 hours, 1 hour to 25 hours, 1 hour to 30 hours, 1 hour to 35 hours, 1 hour to 40 hours, 1 hour to 45 hours, 1 hour to 50 hours, 1 hour to 55 hours, 1 hour to 60 hours, 1 hour to 65 hours, or 1 hour to 70 hours. In specific examples, the first predetermined time is from 5 hours to 10 hours, 5 hours to 15 hours, 5 hours to 20 hours, or 5 hours to 25 hours. In some examples, the first predetermined time is from 5 hours to 6 hours, 6 hours to 7 hours, 7 hours to 8 hours, 8 hours to 9 hours, 9 hours to 10 hours, 10 hours to 11 hours, 11 hours to 12 hours, 12 hours to 13 hours, 13 hours to 14 hours, or 14 hours to 15 hours. In further examples, the first predetermined time is from 8 hours to 8 hours and 30 minutes, 8 hours and 30 minutes to 9 hours, 9 hours to 9 hours and 30 minutes, 9 hours and 30 minutes to 10 hours, 10 hours to 10 hours and 30 minutes, 10 hours and 30 minutes to 11 hours, 11 hours to 11 hours and 30 minutes, 11 hours and 30 minutes to 12 hours. In certain examples, the first predetermined time is from 9 hours to 9 hours and 20 minutes, 9 hours and 20 minutes to 9 hours and 40 minutes, 9 hours and 40 minutes to 10 hours, 10 hours to 10 hours and 20 minutes, 10 hours and 20 minutes to 10 hours and 40 minutes, 10 hours and 40 minutes to 11 hours.

In some examples, the second predetermined time is from 1 minute to 72 hours. In further examples, the second predetermined time is from 1 minute to 1 hour, 1 hour to 5 hours, 5 hours to 10 hours, 10 hours to 15 hours, 15 hours to 20 hours, 20 hours to 25 hours, 25 hours to 30 hours, 30 hours to 35 hours, 35 hours to 40 hours, 40 hours to 45 hours, 45 hours to 50 hours, 50 hours to 55 hours, 55 hours to 60 hours, 60 hours to 65 hours, 65 hours to 70 hours, or 70 hours to 75 hours. In certain examples, the second predetermined time is from 1 hour to 5 hours, 1 hour to 10 hours, 1 hour to 15 hours, 1 hour to 20 hours, 1 hour to 25 hours, 1 hour to 30 hours, 1 hour to 35 hours, 1 hour to 40 hours, 1 hour to 45 hours, 1 hour to 50 hours, 1 hour to 55 hours, 1 hour to 60 hours, 1 hour to 65 hours, or 1 hour to 70 hours. In specific examples, the second predetermined time is from 5 hours to 10 hours, 5 hours to 15 hours, 5 hours to 20 hours, or 5 hours to 25 hours. In some examples, the second predetermined time is from 5 hours to 6 hours, 6 hours to 7 hours, 7 hours to 8 hours, 8 hours to 9 hours, 9 hours to 10 hours, 10 hours to 11 hours, 11 hours to 12 hours, 12 hours to 13 hours, 13 hours to 14 hours, or 14 hours to 15 hours. In further examples, the second predetermined time is from 8 hours to 8 hours and 30 minutes, 8 hours and 30 minutes to 9 hours, 9 hours to 9 hours and 30 minutes, 9 hours and 30 minutes to 10 hours, 10 hours to 10 hours and 30 minutes, 10 hours and 30 minutes to 11 hours, 11 hours to 11 hours and 30 minutes, 11 hours and 30 minutes to 12 hours. In certain examples, the second predetermined time is from 9 hours to 9 hours and 20 minutes, 9 hours and 20 minutes to 9 hours and 40 minutes, 9 hours and 40 minutes to 10 hours, 10 hours to 10 hours and 20 minutes, 10 hours and 20 minutes to 10 hours and 40 minutes, 10 hours and 40 minutes to 11 hours.

In some examples, the inflitration can occur at a temperature of from 40° C. to 150° C. In further examples, the method occurs at a temperature of from 40° C. to 50° C., 50° C. to 60° C., 60° C. to 70° C., 70° C. to 80° C., 80° C. to 90° C., 90° C. to 100° C., 100° C. to 110° C., 110° C. to 120° C., 120° C. to 130° C., 130° C. to 140° C., or 140° C. to 150° C. In specific examples, the method occurs at a temperature of from 50° C. to 55° C., 55° C. to 60° C., 60° C. to 65° C., 65° C. to 70° C., 70° C. to 75° C., 75° C. to 80° C., 80° C. to 85° C., and 85° C. to 90° C. In certain examples, the method occurs at a temperature of from 60° C. to 62° C., 62° C. to 64° C., 64° C. to 66° C., 66° C. to 68° C., 68° C. to 70° C., 70° C. to 72° C., 72° C. to 74° C., 74° C. to 76° C., 76° C. to 78° C., or 78° C. to 80° C. In some examples, the method occurs at a temperature of from 60° C. to 64° C., 60° C. to 66° C., 60° C. to 68° C., 60° C. to 70° C., 60° C. to 72° C., 60° C. to 74° C., 60° C. to 76° C., or 60° C. to 78° C. In further examples, the method occurs at a temperature of from 65° C. to 66° C., 66° C. to 67° C., 67° C. to 68° C., 68° C. to 69° C., 69° C. to 70° C., 70° C. to 71° C., 71° C. to 72° C., 72° C. to 73° C., 73° C. to 74° C., or 74° C. to 75° C. In specific examples, the method occurs at a temperature of from 65° C. to 67° C., 65° C. to 68° C., 65° C. to 69° C., 65° C. to 70° C., 65° C. to 71° C., 65° C. to 72° C., 65° C. to 73° C., or 65° C. to 74° C.

A number of embodiments of the disclosure have been described. Nevertheless, it will be understood that various modifications may be made without departing from the spirit and scope of the invention. Accordingly, other embodiments are within the scope of the following claims.

By way of non-limiting illustration, examples of certain embodiments of the present disclosure are given below.

### EXAMPLES

The following examples are set forth below to illustrate the methods and results according to the disclosed subject matter. These examples are not intended to be inclusive of all aspects of the subject matter disclosed herein but rather to illustrate representative methods and results. These examples are not intended to exclude equivalents and variations of the present invention, which are apparent to one skilled in the art.

Efforts have been made to ensure accuracy with respect to numbers (e.g., amounts, temperature, etc.), but some errors and deviations should be accounted for. Unless indicated otherwise, parts are parts by weight, the temperature is in ° C. or is at ambient temperature, and pressure is at or near atmospheric. There are numerous variations and combinations of reaction conditions, e.g., component concentrations, temperatures, pressures, and other reaction ranges and conditions, that can be used to optimize the product purity and yield obtained from the described process. Only reasonable and routine experimentation will be required to optimize such process conditions.

### Example 1: VPI and Hybrid TiOₓ:Spiro-OMeTAD Layer

### Introduction

Despite the rapid increase in the power conversion efficiency (PCE) of perovskite solar cells (PSCs) in the last decade, stability is still a major roadblock to the commercialization of these devices. An exemplary vapor phase infiltration (VPI) tool and method are disclosed to create a hybrid TiOₓ:Spiro-OMeTAD layer and improve the stability of the organic charge transport layers, such as hole-selective Spiro-OMeTAD.

From X-ray photoelectron spectroscopy (XPS), ultraviolet photoelectron spectroscopy (UPS), and grazing incident wide-angle X-ray scattering (GIWAXS) analysis, it was identified that TiOX infiltration can hinder the crystallization of the Spiro-OMeTAD layer likely by preventing the π-π* stacking of the molecules. Infiltrated PSCs retained around 80% of the original efficiency after an operando stability test of 60 h at 75° C. doubled the efficiency retained by devices without infiltration. The example system and method were employed to stabilize current organic charge transport layers via prevention of π-π* stacking that leads to crystallization, e.g., that shortens device lifetimes.

In some examples, infiltration using indium-oxide infiltration, nickel-oxide, zinc-oxide, copper-oxide, aluminum oxide, titanium oxide, vanadium-oxide, or any combination thereof was employed.

Vapor phase infiltration (VPI) is used to create inorganic-organic hybrid materials with unique properties. It was found that performing VPI on polymers or compounds comprising organic molecules disclosed herein resulted in a bulk-modified hybrid material rather than a surface coating on a substrate, enabling improved chemical stability and modified thermal properties. In this example, a solid polymer or small molecule substrate was exposed to a metal-containing precursor (e.g., metalorganics, metal halides) in the vapor phase. VPI of the Spiro-OMeTAD film was done to improve the device stability by infiltration and hybridization. It was observed that TiO_{X} infiltration hindered the crystallization of the Spiro-OMeTAD layer, thereby preventing the π-π* stacking of the molecules and improving the long-term stability of the devices under thermal stress.

### Experimental Results and Examples

### Hybrid TiOx/Spiro-OMeTAD Films

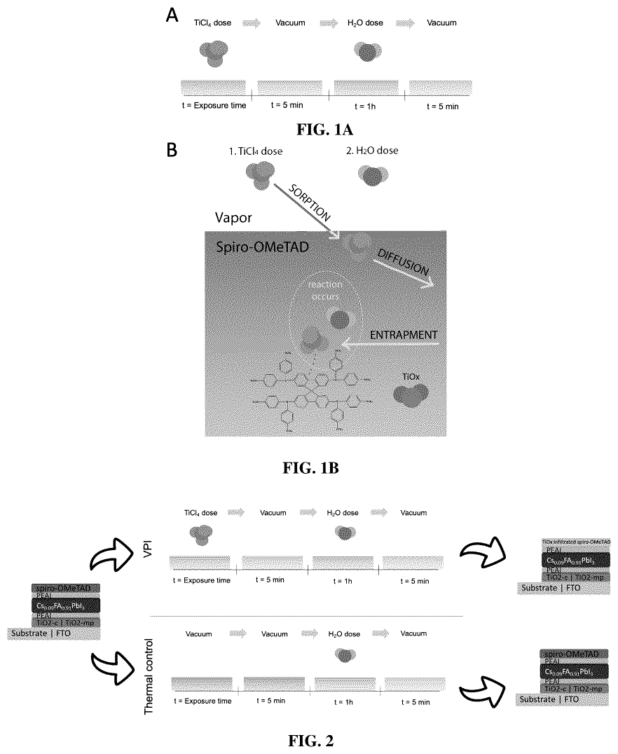

VPI infusion of TiO_{X}-containing hybrid materials was achieved using titanium tetrachloride (TiCl₄) and water vapor as infiltration precursors. FIG. 1A provides a schematic of this VPI process. TiCl₄ was selected for its high reactivity and smaller molecular size compared to its alkylamido and alkoxide counterparts. Within Spiro-OMeTAD and at the film surface, water vapor reacts with accessible TiCl₄ species by an exchange reaction between the water hydroxyl groups and the chlorine ligands to form titanium oxide/hydroxide (TiOₓ) clusters. The rate of infiltration, amount of inorganic loading, and chemical reaction with the polymer were, in some cases, varied with VPI process temperature and precursor exposure time.

To perform VPI, the entire device stack (FTO|c-TiO₂|mp-TiO₂|PVK|Spiro-OMeTAD*, where * indicates the stack surface) was placed in a hot-walled vacuum chamber, maintained at 70° C., and pumped down to medium vacuum (30 mTorr). The substrate was held for 30 minutes at these conditions prior to infiltration to remove sorbed water and residual solvents that may react with the precursor. The reactor was then isolated, and 0.5 Torr/˜0.53 moles of TiCl₄ precursor was introduced (FIG. 1A, “TiCl₄ dose”).

The exposure time to TiCl₄ varied from 3 to 10 h. During this time, the precursor adsorbs to the surface of the Spiro-OMeTAD substrate and undergoes absorption, as shown in FIG. 1B. After being absorbed, the precursor diffused through the substrate, with the potential to coordinate with accessible organic functional groups. The kinetics of this process are complex and depend upon free volume, precursor (concentration, size, and solubility), reaction energetics, and the structure of the hybrid material as it forms. Then, a subsequent 5-minute pumping step was employed to remove the precursor overpressure, labeled in FIG. 1A as a “vacuum.” Water vapor was rapidly introduced to co-react with chemically interacting and free-diffusing precursors within the films. In the final step, water and volatile byproducts were removed by another 5-minute pumping step. FIG. 1B schematically summarizes the mechanisms for the infiltration of TiCl₄ into Spiro-OMeTAD as sorption, diffusion, and entrapment.

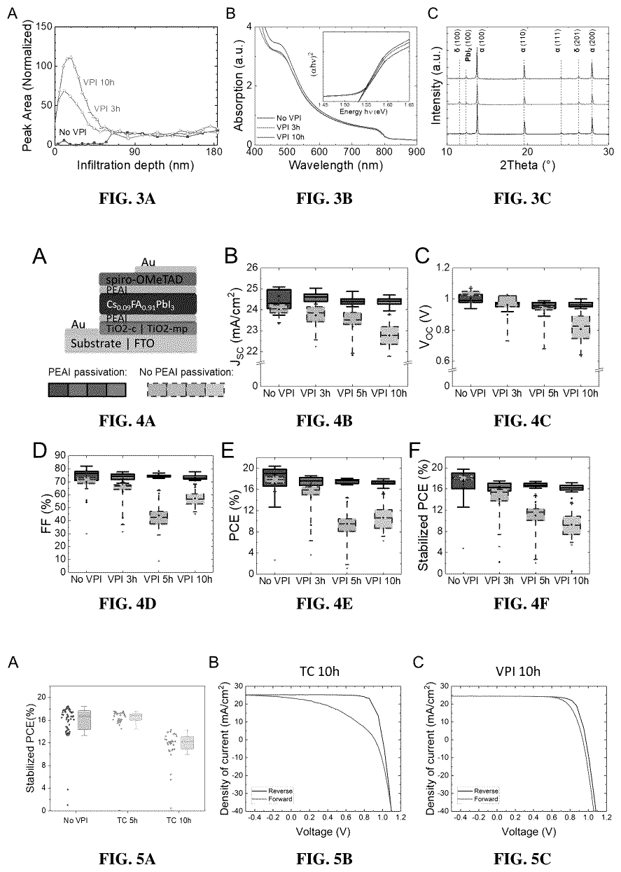

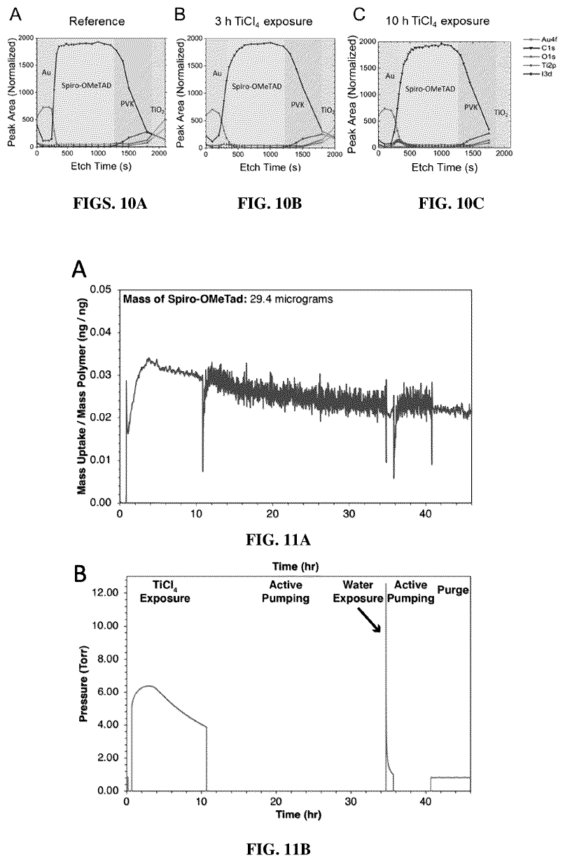

The role of TiCl₄ exposure time in the infiltration process was studied first. The infiltration temperature was set to 70° C. to favor infiltration of TiCl₄ into the Spiro-OMeTAD without triggering the crystallization of the layer. Exposure times up to 10 h at 70° C. were used for the VPI of Spiro-OMeTAD on different substrates. FIG. 9A-FIG. 9E shows the VPI chamber pressure profiles for the studied conditions. X-ray photoelectron spectroscopy (XPS) depth profiling was performed to analyze the elemental composition as a function of depth into the Spiro-OMeTAD layer and to understand how TiO_{X} infiltration varies under different process parameters. FIG. 3A presents the elemental signals with normalized peak area for C is and Ti 2p for the (A) reference (No VPI), (B) 3 h TiCl₄ exposure (VPI 3h), and (C) 10 h TiCl₄ exposure (VPI 10h) against etch depth into the Spiro-OMeTAD layer. FIG. 10A-FIG. 10C presents the complete XPS depth profile for the entire device stack from the gold contacts through the perovskite. It was found that the Ar sputter time through the Au contact layer to reach the Spiro-OMeTAD layer was consistent for each device stack. The similar etch profile for each device shown in FIG. 10A-FIG. 10C demonstrates the reproducibility of the layers. As seen in FIG. 3A, the TiCl₄ exposure time affects the amount and depth of titanium oxide infiltrated in the Spiro-OMeTAD layer. The Ti 2p peak area at the interface Spiro-OMeTAD|Au for the 10 h TiCl₄ exposure is approximately double in value compared to that of the 3 h TiCl₄ exposure. However, for both infiltrated films, the Ti 2p peak quickly fades with additional etching into the bulk of the film. The TiO_{X} infiltration depth is not significantly different for the two infiltration times tested. The infiltration depth is estimated to be 30 nm for the 3 h TiCl₄ exposure and 40 nm for the 10 h TiCl₄ exposure. The etch depth in FIG. 3A was calculated based on the etch time required to remove the Spiro-OMeTAD layer and the thickness measured by SEM and ellipsometry. The interfaces with the perovskite and Au layers were determined from the Au 4f and I 4D signals in FIG. 10A-FIG. 10C. For both infiltration conditions, the O:Ti ratio is closer to 1 than to 2, so the Ti present is not in stoichiometric TiO₂ coordination and therefore is called TiO_{X}.

To evaluate the ability to infiltrate the complete Spiro-OMeTAD layer with increasing exposure times, in situ quartz crystal microbalance (QCM) gravimetry data was collected in a smaller, analysis-oriented VPI reactor. Note that this QCM data does not provide absolute information regarding TiCl₄ and Spiro-OMeTAD sorption, diffusion, and entrapment kinetic for the devices in this work because it was collected in a different chamber with a different TiCl₄ exposure pressure than the chamber used for the device depositions in this report. However, this data does inform the limits, in terms of loading and infiltration depth, of infiltrating Spiro-OMeTAD with TiCl₄. In situ QCM data (FIG. 11A-FIG. 11B) indicates rapid mass uptake occurs within the first hour with a subsequent gradual increase in uptake over the next hour that ultimately reaches a plateau. As such, there is an inherent limit to the amount of infiltration that can occur, making it unlikely to infiltrate the entire Spiro-OMeTAD film thickness in the device stack under the conditions (particularly temperature) explored in this work. In terms of process parameters, this confirms diminishing returns with increasing TiCl₄ exposure time. Additionally, in employing a 24-hour active vacuum pumping step after the TiCl₄ exposure, QCM revealed that ˜30% of precursor desorbs. This provides the mechanistic insight that some TiCl₄ is interacting with the Spiro-OMeTAD film during this active pumping step, such that it is trapped within the Spiro-OMeTAD layer. This trapped TiCl₄ is oxidized during the water vapor exposure step and bound as TiO_{X} within the Spiro-OMeTAD film.

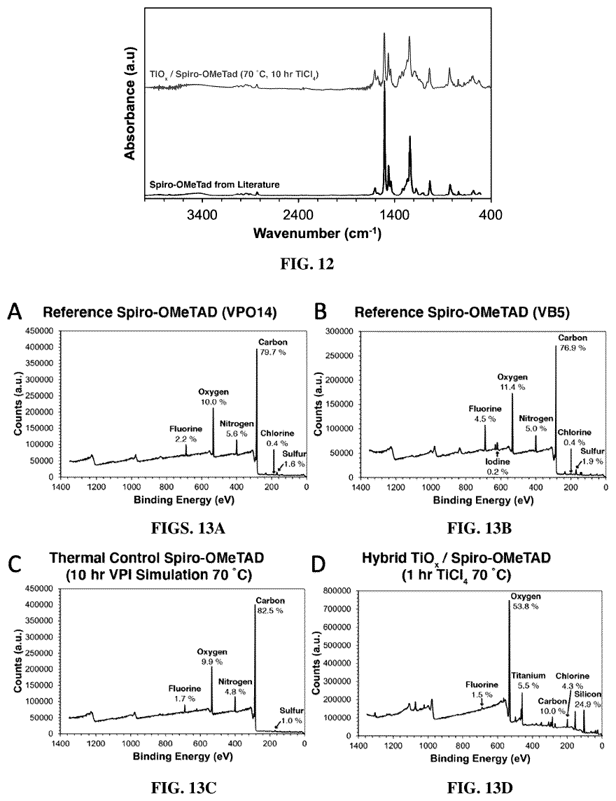

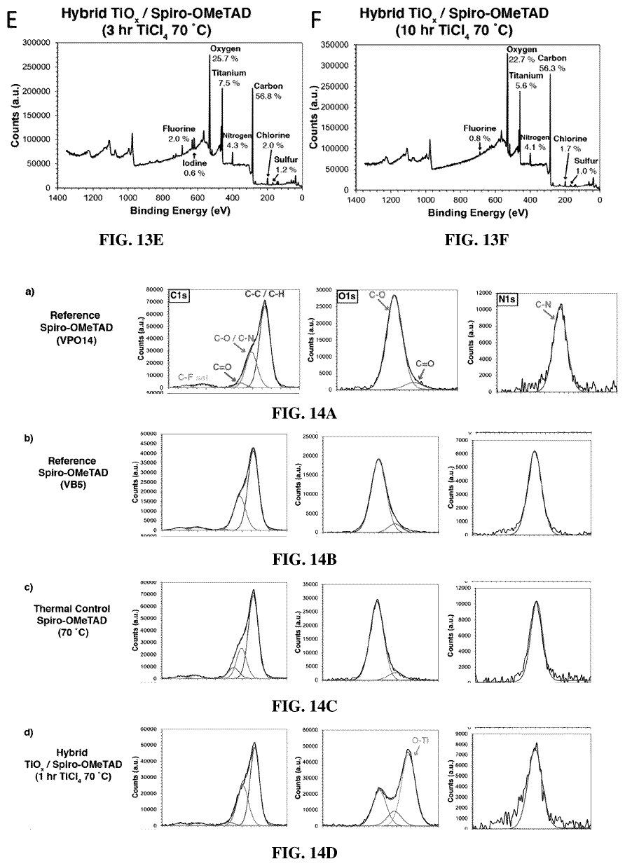

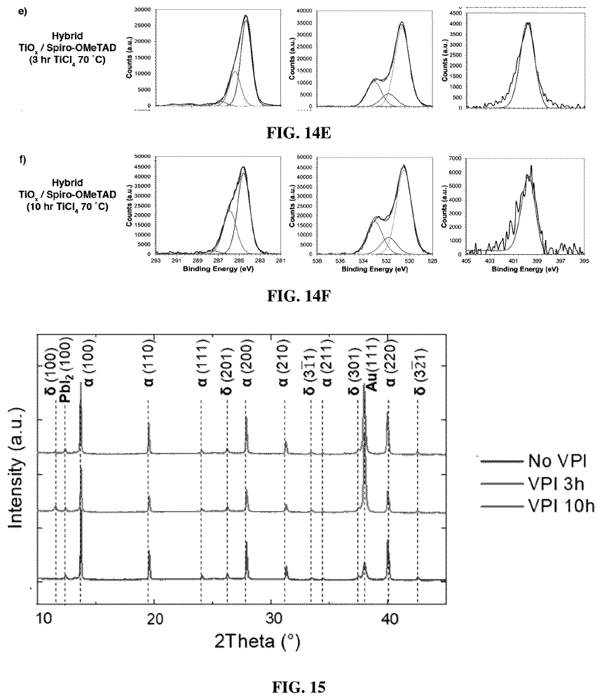

Chemical analysis by Fourier transform infrared spectroscopy (FTIR) (FIG. 12) and XPS surface scans (FIG. 13A-FIG. 13F, FIG. 14A-FIG. 14F) was performed on the resultant TiO_{X}:Spiro-OMeTAD hybrid material to determine the extent of interactions. The FTIR spectra shows slight to no changes after infiltration when compared to the pristine films. This lack of chemical change in a polymer upon infiltration has been observed in several other VPI systems and suggests minimal persistent chemical interactions between the inorganic TiO_{X} and Spiro-OMeTAD. From surface core level XPS spectra, the presence of Ti—O bonding is confirmed in the Ti 2p and O 1s spectra after infiltration (FIG. 14A-FIG. 14F). Additionally, there is a notable difference in the C 1s spectra after infiltration once peak deconvolution is performed. The C is satellite peak at ˜291.5 eV, indicative of Spiro-OMeTAD π-π* stacking, is disrupted after infiltration. For short TiCl₄ exposures, 1 h and 3 h, the satellite peak has decreased in size compared to the neat Spiro-OMeTAD. For the 10 h TiCl₄ exposure, the satellite peak is not present. To ensure the decreasing satellite peak is not caused by temperature effects, a thermal control was also measured. A process schematic describing the thermal control processing is presented in FIG. 2.

For the thermal control, the satellite peak remains similar in size and position to the reference Spiro-OMeTAD. Therefore, this disruption in Spiro-OMeTAD π-π* stacking is likely caused by TiO_{X} infiltration and indicates a structural difference in the Spiro-OMeTAD film, although no obvious chemical bonding between Spiro-OMeTAD and TiO_{X} is detected by XPS nor FTIR. This further suggests that TiO_{X} has physical interactions (e.g., some type of secondary bonding) with Spiro-OMeTAD but does not form any primary covalent bond.

Ultraviolet-visible (UV-VIS) absorption spectra and X-ray diffraction (XRD) scans were also collected to evaluate the stability of the perovskite layer in semi-complete PSCs stacks (FTO|c-TiO₂|mp-TiO₂|PVK|Spiro-OMeTAD*) where the Spiro-OMeTAD layer was infiltrated with different exposure times. FIG. 3B shows that VPI does not significantly modify the absorption edge of the perovskite layer, which is at around 800 nm. Additionally, the XRD scans for each condition (FIG. 3C, FIG. 15) demonstrate no changes in the crystalline peak positions, indicating VPI does not affect the bulk of the perovskite layer. It is worth noting that for the 3 h exposure time, the pattern shows a small peak at 2θ=11.5° that corresponds to the plane (100) of δ-FAPbI₃, which could indicate some degradation of the layer. However, this peak is not observed with a longer exposure time of 10 h. Moreover, peaks for the planes (201) and (31̅1) of δ-FAPbI₃ are present in the devices. As such, the presence of δ-FAPbI₃ was determined not to be caused by the VPI process. Interestingly, XRD scans of the complete devices (FTO|c-TiO₂|mp-TiO₂|PVK|Spiro-OMeTAD|Au*) show that VPI induces the formation of a more ordered gold film on top of infiltrated Spiro-OMeTAD layers, as suggested by the increased intensity of the peak at 2θ=38.1° that corresponds to the plane (111).

### Fabrication and Characterization of Infiltrated PSCs

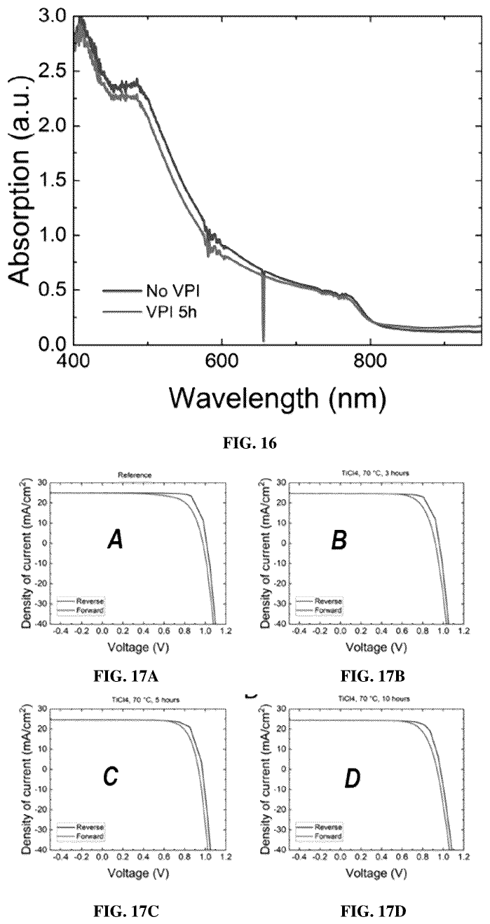

Spiro-OMeTAD films infiltrated with TiO_{X} were incorporated as the HTL in a complete solar cell (FIG. 4A). Compact-TiO₂ and mesoporous-TiO₂ were used as the electron transport layers (ETL) and were coated with the perovskite film following the procedure described in the experimental section. Phenylethylammonium iodide (PEAI) was deposited by spin coating before and after the deposition of the perovskite layer for a dual surface passivation effect. The phenyl group of PEAI is hydrophobic and increases the water resistance of perovskite films. This surface treatment is prevented drops in PCE after VPI of the Spiro-OMeTAD (FIG. 4B-FIG. 4F), with the hydrophobic PEAI layer protecting the underlying perovskite layer during the exposure of TiCl₄ and water in the VPI process. If no PEAI is used at the perovskite surface before the VPI treatment, the V_{OC} and fill factor (FF) drop below 0.95 V (80 mV loss) and 50%, respectively, in devices fabricated with 5 h of exposure time (VPI 5h), as shown in FIGS. 4C and 4D. Since the UV-VIS absorption (FIG. 16) showed that the bulk of the perovskite layer did not change during the VPI process even when PEAI passivation was not used, the TiO_{X} infiltration played a role at the perovskite|Spiro-OMeTAD interface. This change at the interface was responsible for higher recombination in the devices with VPI, which caused the drop in the performance, but this effect is suppressed by the PEAI.

Devices with PEAI surface treatment show improved stability under VPI processing. The short circuit density of current (J_{SC}) and FF of the solar cells do not change significantly in devices fabricated with TiCl₄ exposure times varying between 0 and 10 h (FIG. 4B and FIG. 4D). The devices show an average J_{SC} of around 24 mA/cm² and an average FF of 75%. However, the V_{OC} decreases slightly, by approximately 50 mV, in TiO_{X} infiltrated devices (FIG. 4C), lowering the PCE with respect to the reference non-infiltrated samples (FIG. 4E). The V_{OC} drop does not change for longer TiCl₄ exposure times (up to 10 h). As a result, the PCE of passivated devices remains constant for TiCl₄ exposure times between 3 h and 10 h, showing an average stabilized PCE of around 16.5%. Overall, the PCE of infiltrated devices remains approximately 1.5% lower than in the devices that have a Spiro-OMeTAD layer without VPI, as shown in FIG. 4E and FIG. 4F. Table 1 summarizes the performance parameters of champion devices with and without PEAI passivation, and the J-V curves are shown in FIG. 9A-FIG. 9E.

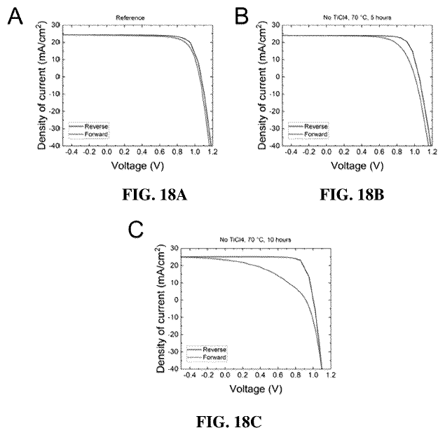

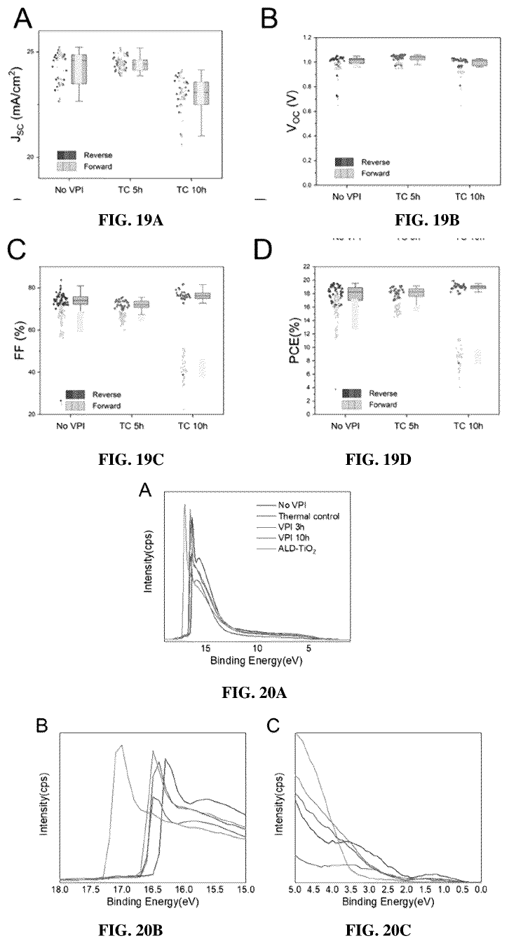

To further investigate the origin of the decrease in the VOC, PSCs were fabricated with Spiro-OMeTAD layers that underwent a thermal control process (full VPI treatment at 70° C. without the introduction of precursor) at different times (FIG. 18A-FIG. 20C). This experiment disentangles the contribution of the TiCl₄ precursor exposure from the effect of the temperature and water vapor on the PSC performance. Both temperature and water vapor have a negligible impact on the PCE measured from reverse J-V scans. V_{OC}, J_{SC}, and FF remain unchanged for heating times of up to 10 h. However, temperature plays a role in the hysteresis of the devices, as observed in FIG. 9A-FIG. 9E. Longer heating times increase the hysteresis, impacting the PCE of the device under steady-state operation. These changes are reflected in the stabilized PCE (FIG. 5C), which shows that the process hurts the overall performance of the device. FIG. 9A-FIG. 9E summarizes the performance parameters taken from the J-V scans. The FF is the parameter that is most affected by the hysteresis of the devices, decreasing to around 40% in forward scans when the exposure time was 10 h, against the reference FF at 65%. The hysteresis observed in the thermal control is higher than in VPI devices, as observed when comparing FIG. 5B and FIG. 5C. This difference stems from different degrees of the interaction of water vapors with the perovskite film that lead to increased ionic migration under bias. Conversely, samples with TiO_{X} infiltrated in the Spiro-OMeTAD films prevent further diffusion of the water molecule through the film.

TABLE 1
Electrical performance parameters of the champion device fabricated with varying
exposure time

| | PEAI Passivation | | | | | No PEAI Passivation | | | | |
|---|---|---|---|---|---|---|---|---|---|---|
| | | | | | Stab. | | | | | Stab. |
| | J_{SC} | V_{OC} | FF | PCE | PCE | J_{SC} | V_{OC} | FF | PCE | PCE |
| | (mA/cm²) | (V) | (%) | (%) | (%) | (mA/cm²) | (V) | (%) | (%) | (%) |
| No | 24.97 | 1.05 | 77.27 | 20.26 | 19.53 | 24.23 | 1.06 | 72.72 | 18.68 | 18.60 |
| VPI | | | | | | | | | | |
| VPI | 25.03 | 0.96 | 77.44 | 18.61 | 17.53 | 24.26 | 1.02 | 67.09 | 16.6 | 16.04 |
| 3 h | | | | | | | | | | |
| VPI | 24.34 | 0.99 | 75.08 | 18.09 | 17.45 | 23.39 | 0.97 | 63.87 | 14.49 | 14.75 |
| 5 h | | | | | | | | | | |
| VPI | 24.41 | 0.97 | 74.64 | 17.67 | 17.14 | 23.67 | 0.94 | 68.23 | 15.18 | 13.48 |
| 10 h | | | | | | | | | | |

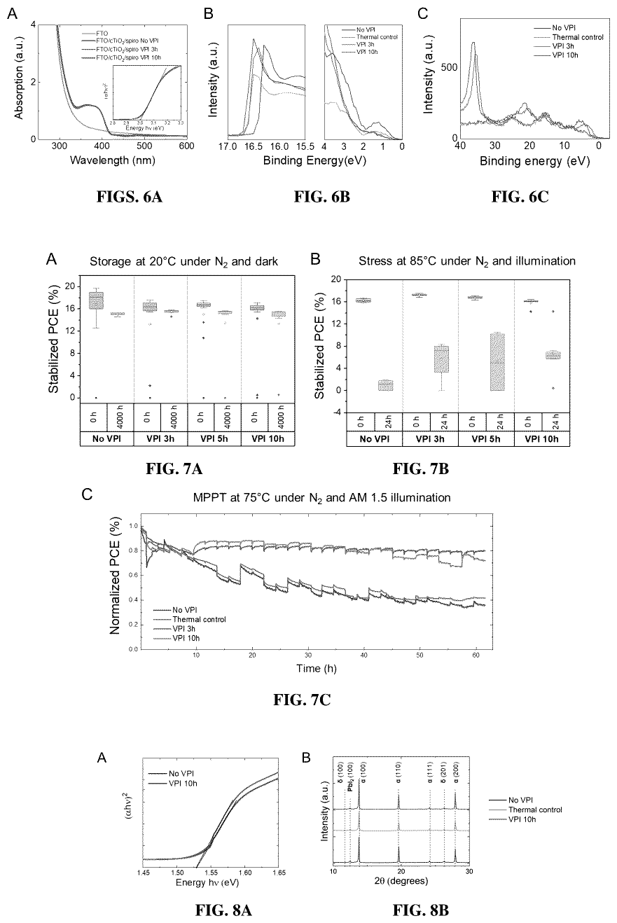

Although the performance loss in the thermal control revealed some degradation of the devices, the decrease in V_{OC} when infiltrating the Spiro-OMeTAD layer with TiO_{X} was not triggered by the temperature and water vapor in the VPI process but was rather a consequence of the presence of TiO_{X} in the Spiro-OMeTAD layer. TiO₂ can block holes in a perovskite solar cell as it has a deep valence band. It was found that TiOₓ VPI only penetrates 30-40 nm into the Spiro-OMeTAD layer, as shown in FIG. 3A, and does not form a continuous layer as in ALD. Thus, the injection of holes from the perovskite layer into the Spiro-OMeTAD should not be affected. The presence of TiO_{X} near the interface with gold can create a barrier that dramatically affects the performance of the device. However, TiO_{X} infiltration only causes a mild decrease in the V_{OC} of PSCs. A change in bandgap or in the position of the energy levels of the TiO_{X}:Spiro-OMeTAD layer could explain the drop in Voc. However, FIG. 6A shows that the UV-Vis absorption spectrum of Spiro-OMeTAD does not change after the infiltration with TiO_{X}. As such, a change in the bandgap of the HTL is not the cause of the observed decrease in the V_{OC} of devices, as corroborated by the Tauc plot in the inset of FIG. 6A. Nonetheless, ultraviolet photoelectron spectroscopy (UPS) in FIG. 6B and FIG. 9A-FIG. 9E shows that the position of the valence band changes on the surface after infiltration. The calculated work function was −5.06 eV for the untreated films and a work function of −7.1 eV for the infiltrated films, which does not change significantly for TiCl₄ exposure times between 3 h and 10 h. To investigate the role of TiO_{X} in the UPS results, 20 nm was deposited of TiO₂ by ALD on top of an untreated Spiro-OMeTAD layer. UPS shows that the work function of the TiO₂ layer is −7.34 eV, showing that TiO_{X} dominates the signal in the infiltrated Spiro-OMeTAD layers. A comparison of the shape of the UPS scans suggests that there is also some signal being obtained from the Spiro-OMeTAD on the surface of the infiltrated samples. Moreover, it has also been shown that defects in the structure of TiO_{X} form deep traps that can transport holes in PSCs²³, which can also mitigate the energetic barrier. Therefore, it is possible that holes are being transported by the Spiro-OMeTAD in the hybrid film or by the TiO_{X} clusters themselves, or by both.

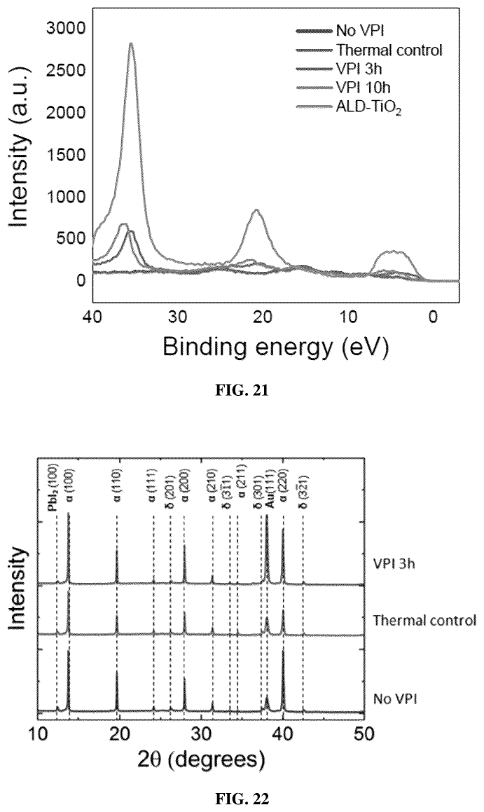

To better understand the energetics of the VPI-treated Spiro-OMeTAD surface, the XPS valence scan (FIG. 6C and FIG. 21) was examined, which was taken as an approximation of the density of states (DOS) on the surface of the samples. The spectra show that the DOS of infiltrated samples has contributions from both TiO_{X} and Spiro-OMeTAD, and therefore, the energy levels of Spiro-OMeTAD can contribute to the transport of holes and mitigate the potential energetic barrier, in case there is one, that was created by the presence of TiO_{X}.

Despite VPI lowering the initial performance of the solar cells, infiltrated devices have improved long-term stability compared to the reference, as shown in FIG. 7A. After 4000 h of storage in the dark at room temperature and in a nitrogen environment, the reference devices lost about 16% of the initial efficiency (to an average stabilized PCE of 15%). On the other hand, infiltrated devices only lost about 6% of their initial efficiency (to an average stabilized PCE of 16%). The performance drop is mainly attributed to a decrease in FF and J_{SC}. After 4000 h, the reference devices lost about 10% of FF and 1 mA/cm² of J_{SC}.

The effect of VPI on stability was seen more clearly when stressing the devices at high temperatures and under illumination (FIG. 7B). The devices were stressed by heating the cells to 85° C. on a hotplate (at the open circuit) for 24 h in a nitrogen environment and exposed to 1 Sun equivalent illumination by a commercial LED lamp. After the stress test, the reference devices yield a median stabilized PCE of 1.1%, whereas the TiO_{X} infiltrated devices provide a stabilized PCE of around 6%. Further stability measurements were carried out by tracking the maximum power point of the devices while keeping constant the temperature of the films (by Peltier pads) at 75° C. under AM1.5 illumination. The MPPT was interrupted every two hours to measure J-V curves under dark and illumination conditions. FIG. 7C compares the average normalized efficiency obtained in the test. In the first 10 h, the devices suffer a similar decay in performance, losing around 20% of the original PCE. For longer stress times, infiltrated devices with an exposure time between 3 and 10 h reach a plateau in efficiency, but devices without VPI continue to drop until reaching 40% of the starting efficiency after 60 h.

### Degradation Mechanisms of PSCs

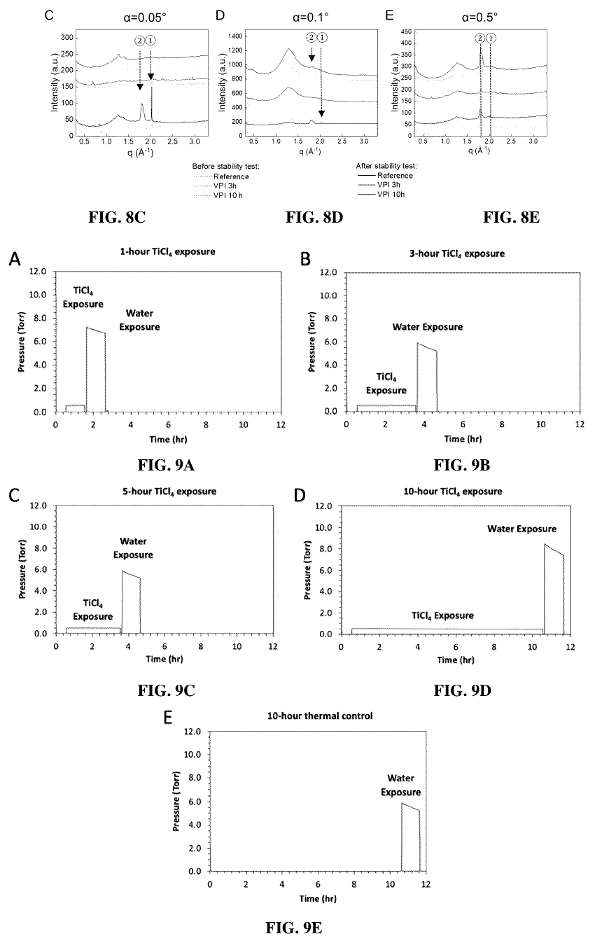

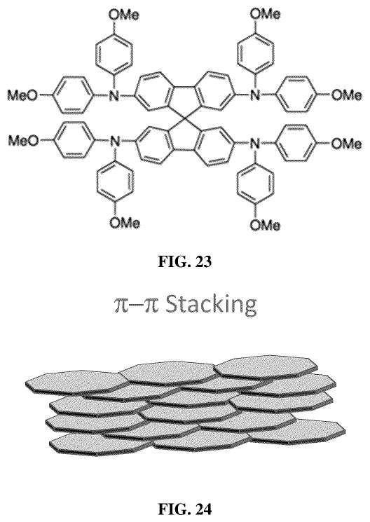

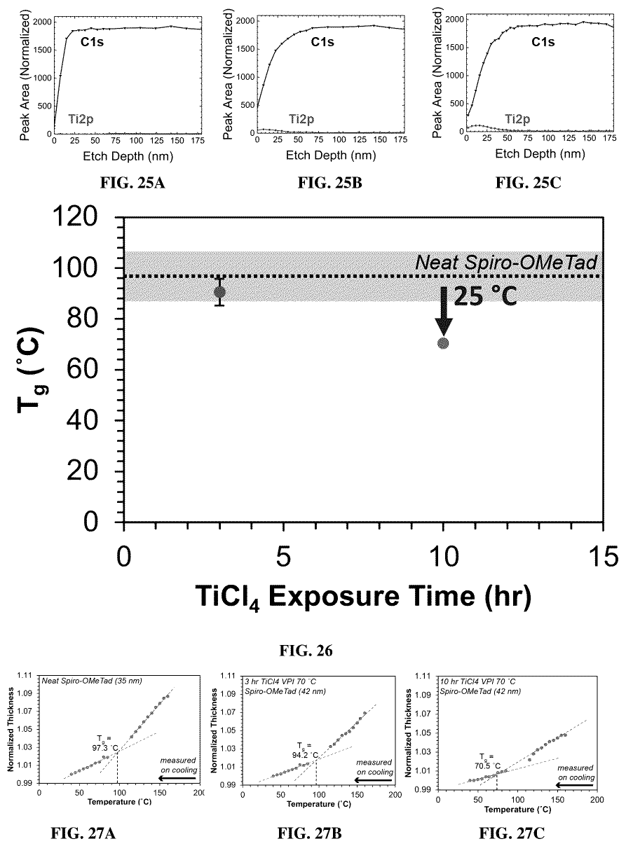

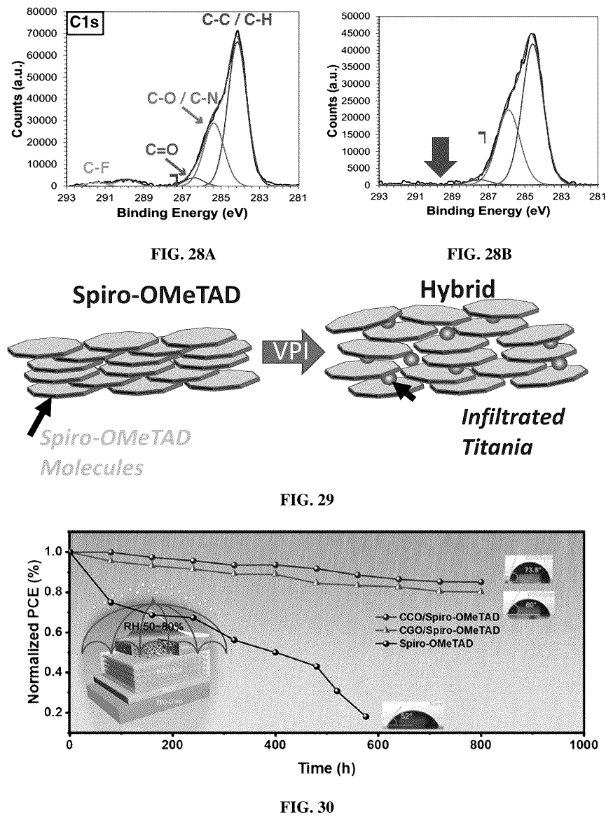

To understand the potential degradation mechanisms that led to the drop in efficiencies in these PSCs, UV-vis spectroscopy and x-ray diffraction of the films were conducted. UV-VIS absorption spectra of devices taken before and after degradation show that the onset at around 800 nm remains unchanged (FIG. 8A, 1.54 eV from the Tauc plot), suggesting that, despite changes happening in the layer, the bulk of the perovskite is not affected by the stress test at high temperature and illumination. XRD confirms that the bulk of the perovskite layer is predominantly cubic and that the intensity of the peaks of δ-FAPbI₃ does not increase, as shown in FIGS. 8B and 22. Therefore, these observations suggest the degradation is likely to happen in a different layer or at an interface.

Spiro-OMeTAD has historically had low stability under thermal stress. Crystallization has been shown to occur in Spiro-OMeTAD layers with exposure to temperatures as low as 75° C., leading to the formation of cracks and delamination^{15,46} To investigate if the loss in performances of the solar cells after the stress test was dominated by Spiro-OMeTAD crystallization, GIWAXS of the films was measured before and after thermal treatment at 85° C. for 48 h under illumination. The circular integration of the GIWAXS pattern was taken with incident angles (u) from 0.050 to 0.5° of Spiro-OMeTAD layers deposited on silicon wafers and monitored the impact of different TiCl₄ exposure times. Since the penetration depth of the X-rays varies based on the incident angle, this data enables us to compare the crystallinity at the surface with the bulk of the Spiro-OMeTAD layer. The results are presented in FIG. 8C, FIG. 8D, and FIG. 8E. The surface (α=0.05°) of the Spiro-OMeTAD layer had the biggest difference between untreated and infiltrated samples. Before thermal stress, the Spiro-OMeTAD layers are predominately amorphous. However, the Spiro-OMeTAD without VPI treatment shows a small peak located at q=2.02 Å⁻¹ which highlights the presence of an undetermined crystalline phase (phase 1). This peak has a reduced intensity in the 3 h infiltrated sample, and it is nonexistent in the 10 h infiltrated samples. On the other hand, the diffraction in the bulk scan (α=0.5°) of the layers is similar and predominantly amorphous. The intensity of the peak attributed to phase 1 decreases in intensity with respect to the surface scan, suggesting that this phase forms preferentially at the surface. Another undetermined crystalline phase (phase 2) is observed in the bulk, which has a predominant peak located at q=1.79 Å⁻¹. There are two different crystal phases present in the film as the peak of phase 2 is broader than the peak observed in phase 1, and no clear relationship between the intensities of these peaks across samples was found. The vapor phase infiltration of TiO_{X} in Spiro-OMeTAD hindered the formation of phase 1.

This trend was made more evident by studying the devices after stressing the Spiro-OMeTAD layers at 85° C. for 48 h under illumination. Untreated Spiro-OMeTAD shows increased crystallinity. The intensity of the phase 1 predominant peak increases by five times, and the phase 2 predominant peak is now evident on the surface. Importantly, these peaks are not present on the surfaces of the infiltrated samples. The bulk of the samples shows only minor changes after the stress. Even though TiO_{X} infiltrated Spiro-OMeTAD is predominantly amorphous, peaks with low intensity appear in the GIWAXS pattern after stressing the layers. Indeed, these peaks are also present in the untreated Spiro-OMeTAD after stress. However, the presence of these peaks does not have a clear relationship with the intensity of the predominant peaks of phase 1 and 2. This leads us to believe that these peaks belong to a different crystalline structure (phase 3 or more phases) that is formed under thermal stress and illumination on the surface of the layer. Pure Spiro-OMeTAD has been demonstrated to crystallize with a triclinic P-1 space group. However, the simulated pattern did not match the positions of the peaks observed in this example. Identification of each of these crystalline phases is complicated due to the use of additives to improve the electrical properties of Spiro-OMeTAD. Li-TFSI, FK-209 Co(III), and tert-butyl pyridine are added to the solution to dope this material, and could interact with Spiro-OMeTAD to induce the formation of different, unidentified crystalline phases.

FTIR, XPS, and UPS suggest that TiO_{X} does not form persistent chemical bonds with the Spiro-OMeTAD molecule. Instead, it infiltrates at the molecular level the top 30-40 nm of the Spiro-OMeTAD film. As previously discussed, FIG. 14A-FIG. 14F shows that longer TiCl₄ exposure time decreases the intensity of the π-π* satellite peak in the C is spectra, which disappears with 10 h TiCl₄ exposure, indicating disruption Spiro-OMeTAD inter-molecular p-p bonding. The infiltrated TiO_{X} played a role in hindering the crystallization of the layers by interrupting π-π* stacking between different Spiro-OMeTAD molecules.

### Results

Spiro-OMeTAD deposition: 91 mg of Spiro-OMeTAD (1-Material) were dissolved in 1 mL of chlorobenzene (Acros Organics, 99.9) to form a 0.07 M solution. This solution was doped by adding 16 uL of a 1.8 M Li-TFSI solution in acetonitrile, 9 uL of a 0.25 M FK-209 Co (III) TFSI salt (Sigma-Aldrich) solution in acetonitrile (Sigma-Aldrich, anhydrous 99.8%) and 36 uL of 4 tert-butylpyridine (Sigma-Aldrich, 98%). 90 uL of the final solution was deposited by dynamic spin coating on the substrate as described elsewhere. A thin film of TiO₂ was deposited by spray pyrolysis to improve the coverage of the film when working with FTO and silicon wafer substrates. The thickness of a layer is typically 180 nm.

Vapor Phase Infiltration: Solar cell devices and Spiro-OMeTAD thin films on silicon wafers were infiltrated in a custom-built VPI reactor using the precursor titanium tetrachloride (TiCl₄, Strem Chemicals, 97%) and co-reactant deionized water vapor dosed from a container at room temperature. The devices or doped Spiro-OMeTAD thin films on Si were placed within the heated reactor at 70° C. and pumped down to approximately 30 mTorr rough vacuum with a rotary vane vacuum pump. Pressures were measured with a Baratron capacitance manometer. The chamber was actively pumped for thirty minutes to remove sorbed water. The chamber was then isolated, and the TiCl₄ precursor was dosed into the chamber for 5 s to achieve a TiCl₄ pressure of approximately 500 mTorr in the 1 ft³ chamber volume. The samples were exposed to the static TiCl₄ atmosphere for a variable amount of time (3 h, 5 h, 10 h) as specified throughout this work. The chamber was then pumped for 5 minutes to remove excess TiCl₄. The devices and films were then exposed to 2 to 2.5 Torr of water vapor (from a deionized source) to co-react with the TiCl₄. Water vapor was held in the isolated chamber for 1 h. Then the chamber was pumped for 5 minutes to remove any reaction byproducts and excess H₂O prior to opening the chamber. Samples were removed immediately. Representative pressure profiles for these processes are provided in FIG. 9A-FIG. 9E. The dosing sequences were accomplished with a custom-built control software described previously.

Fabrication of perovskite solar cells: FTO glasses were cleaned by sonicating sequentially for 15 min in a 2% mucasol (Schülke) solution, distilled water, acetone (Sigma-Aldrich, ≥99.5%), and isopropyl alcohol (Fischer Chemical), and then dried with a nitrogen gun. The layer of compact-TiO₂ was deposited by spray pyrolysis from a solution containing 10.8 mL of ethanol (Sigma-Aldrich, ≥99.5%), 480 uL of acetyl acetone (Sigma-Aldrich, anhydrous 99.8%), and 720 uL of titanium diisopropoxide bis(acetylacetonate) 75 wt. % in isopropyl alcohol (Sigma-Aldrich). The deposition was made in seven cycles of 10 s of spraying separated by 30 s from each other. The substrates were kept at 450° C. during the entire process, including 30 min of post annealing. The mesoporous-TiO₂ was deposited by spin coating at 4000 rpm for 10 seconds using a commercial TiO₂ paste (Sigma-Aldrich) that was dissolved in ethanol (Sigma-Aldrich, ≥99.5%) in a 5:1 weight ratio. The mesoporous-TiO₂ layer was dried on a hot plate at 100° C. for at least 10 min, and then annealed at 500° C. for 1 h. The mesoporous-TiO₂ film was then surface treated with 1M solution of phenethylammonium iodide (Dyenamo, >98%) in isopropyl alcohol (Fischer Chemical) via dynamic spin coating at 5000 RPM for 20 seconds.

Cs_{0.09}FAI_{0.91}PbI₃ perovskite films were deposited via spin coating from a 1.1 M solution in a mixture of DMF (Acros Organics, 99.8%+) and DMSO (Acros Organics, ≥99.8%) with a volumetric ratio of 4:1. Typically, 532 mg of PbI₂ (Tokyo Chemical Industry, >98.0%), 172 mg of FAI (Sigma-Aldrich), and 25.7 mg CsI (Sigma-Aldrich) were dissolved in 1 mL of solvent. The spin coating recipe consisted of two steps, the first one being at 1000 rpm for 20 seconds and the second one being at 6000 rpm for 10 seconds. 250 uL of chlorobenzene (Sigma-Aldrich, anhydrous 99.8%) dripped on the substrate 5 seconds before the end of the spinning. The same PEAI surface treatment mentioned above was incorporated on top of the perovskite film.

After deposition of the Spiro-OMeTAD on top of the perovskite layer, 50 nm of gold were evaporated as the back contact using a shadow mask to make 8 independent pixels in a singles substrate. Each of the pixels had an active area of 0.128 cm².

Characterization: XPS was conducted with a Thermo Scientific K-Alpha system using a monochromatic Al Kα X-ray source (1486.6 eV) with a 600 incident angle and a 0° photoemission angle, both measured from the sample normal. Survey and high-resolution scans were collected. High-resolution scans were taken with a 0.100 eV step size for Au4f, C1s, N1s, 14D, O1s, Pb4f, and Ti2p. Depth profiling was performed with 2000 eV etch energy and Ar as the bombarding species. Etch depth was calibrated using the known layer thicknesses in the device stack. UPS was done with a Kratos XPS system.

XRD measurements were done in a third-generation Panalytical Empyrean diffractometer. GIWAXS was performed at the beamline 11-BM at the National Synchrotron Light Source II in Brookhaven National Laboratory. The samples were measured with incidence angles between 0.1 and 0.5 degrees with a 20 second exposure time, using a beam with an energy of 13.5 keV, 0.2 mm×0.05 mm size, 1 mrad divergence, and an energy resolution of 0.7%. UV-VIS absorption spectra were taken with a Cary 5000 UV-vis/NIR spectrometer.

Solar cell photovoltaic parameters were extracted from J-V characteristics collected with a Fluxim solar simulator under AM1.5G illumination, using a scan rate of 50 mV/s. J-V curves were acquired in forward and reversed scans, and the stabilized PCE was taken from a maximum power point track (mppt) of 1 min. For the stability test, a heating stage was used to control the temperature of the devices at 75° C. while tracking the maximum power point. Every two hours J-V curves under dark and AM1.5G illumination were taken to see the evolution of the photovoltaic parameters over time. Finally, after the stability test, the devices were allowed to recover for 12 h in dark conditions and measured at room temperature.

### Discussion

Metal halide perovskite solar cells (PSCs) have shown enormous potential to lower the cost of solar energy. In just a decade, their power conversion efficiency (PCE) has rapidly increased to over 25%, surpassing other technologies, such as CIGS and CdTe, while employing readily available elements.

However, long-term stability remained the major barrier to commercialization. The perovskite layers, especially those containing methylammonium (MA), are susceptible to degradation when exposed to moist air and high temperatures. Studies have shown that alloying MA with Cs- and formamidinium (FA) can improve the thermal stability of the perovskite layer. Cs and FA alloying also allows for tuning the crystallographic structural phase, which ultimately dictates long-term stability. While the perovskite layer has been of concern due to these degradation mechanisms, the charge transport layers have been identified as the main causes of degradation in a PSC. The most commonly used electron transport layer is TiO₂, which absorbs UV light and initiates a photocatalytic degradation of the perovskite layer. Traditional hole transport layers (HTL) are thin films of small molecules, such as Spiro-OMeTAD. Spiro-OMeTAD enables efficient hole collection, which resulted in most of the published world record efficiencies, but it suffers from poor long-term stability.

There are three main degradation pathways for Spiro-OMeTAD during solar cell operation. The first is caused by dopants. Spiro-OMeTAD requires the use of dopant additives to improve its conductivity through the formation of oxidized Spiro[TFSI]₂. Although this is beneficial for the initial performance of the devices, Spiro[TFSI]₂ rapidly reacts with iodide ions that migrate from the perovskite layer and reduces back to Spiro-OMeTAD, which decreases the conductivity of the layer over time. Further, the Spiro-OMeTAD layer allows the migration of gold ions from the back contact into the perovskite layer (second pathway), which has been suggested as another route to the irreversible degradation of PSCs. The third degradation pathway for this charge transport layer involves the crystallization of Spiro-OMeTAD at temperatures as low as 65° C. Studies have shown that degradation of the Spiro-OMeTAD layer or the interface between perovskite and Spiro-OMeTAD happens at temperatures where the bulk of the perovskite layer is not significantly degraded. While the perovskite layer can withstand temperatures up to 120° C. without showing signs of degradation in X-ray diffraction (XRD) or ultraviolet-visible (UV-VIS) absorption spectroscopy, the hole mobility of the Spiro-OMeTAD layer decreases when devices are subject to several heating cycles at 70° C. Further, the formation of cracks and delamination has also been observed on Spiro-OMeTAD layers under operation when stressed to 75° C.

Efforts to combat the stability issues of halide perovskite absorbers have focused on changes to selective contact layers from organics to metal oxides. The latter approach has been implemented because most organics crystalize at low temperatures (50-100° C.), leading to cracking and delamination of the thin films and thus to rapid degradation of the device. Recent work has demonstrated that an amorphous TiO₂ layer deposited by atomic layer deposition (ALD) between the Spiro-OMeTAD layer and Au electrodes can improve the performance of perovskite solar cells and prevent diffusion of ions in between layers. ALD is an effective deposition method to grow conformal, pinhole-free thin films to provide stability by encapsulation and has been studied for other PSC applications. However, most metal oxide thin films do not have well-aligned band edges with the HTLs, which can lead to low-charge carrier extraction efficiencies, motivating the search for a hybrid approach where the metal oxide is not blocking the extraction of carriers.

Vapor phase infiltration (VPI) is a deposition technique related to ALD that has been used to form organic-inorganic hybrid materials with unique properties. In contrast to ALD, VPI infuses the gaseous precursors into the subsurface of polymeric materials, leading to chemical reactions with the polymer that form inorganic metal oxide clusters within the polymer. Thus, unlike ALD, which forms a coating on the surface, VPI modifies the bulk chemistry of the polymer, forming a new organic-inorganic hybrid material and modified thermal properties. During the VPI process, a solid polymer or small molecule substrate is exposed to a metal-containing precursor (e.g., metalorganics, metal halides) in the vapor phase. Depending upon precursor chemistry, substrate chemistry, and VPI processing parameters, the precursor will sorb within the film, diffuse, and become entrapped. Entrapment occurs either via chemical interaction with the substrate or by reaction with a co-reactant subsequently introduced, leading to a nonvolatile material (often a metal oxide cluster of just a few atoms).

Spiro-OMeTAD thin films were infiltrated with TiOx clusters to improve the device stability while not compromising solar cell efficiency. Using X-ray photoelectron spectroscopy (XPS) depth profiling, TiO_{X} is found to infiltrate about 30-40 nm into the Spiro-OMeTAD layer. No significant chemical changes are observed in FTIR and XPS, indicating there is no direct chemical bonding between the Spiro-OMeTAD and the infiltrated TiOx clusters. The long-term stability of the PSCs is greatly improved by infiltrating TiO_{X} into the Spiro-OMeTAD films. According to GIWAXS measurements, this improvement in long-term stability appears to be related to the TiOₓ clusters disrupting the π-π stacking of the Spiro-OMeTAD and hindering its crystallization.

### Example 2: TiCl₄—H₂O VPI Modification of Spiro-OMeTAD

Spiro-OMeTAD is a small molecule, hole transport material for organic electronics. (FIG. 41, FIG. 42) Modification occurred with 0 to 10 hr TiCl₄ Exposure (6 Torr), 14 h pump prior to oxidation and 1 h H₂O exposure at 70° C. Infiltration is possible to 30-40 nm.

The duration of time the Spiro-OMeTAD is exposed to TiCl₄ results in varying etch depths which are shown in XPS depth profiles of TiOₓ infiltration graphs. (FIG. 43A-FIG. 43C)

Infiltration via TiCl₄, resulting in the TiOₓ-Spiro hybrids, impacted the glass transition temperature of the Spiro-OMeTAD. (FIG. 44, FIG. 45A-FIG. 45C), as well as other physical changes. (FIG. 46A-FIG. 46B). The inorganics infiltrating the Spiro-OMeTAD disrupt the π-π stacking. (FIG. 47)

Additional data are available in Castro-Méndez et al., “Vapor Phase Infiltration Improves Thermal Stability of Organic Layers in Perovskite Solar Cells,” ACS Energy Lett. 2023, 8, 844-852, which is incorporated by reference.

### Exemplary Aspects:

Example 1. A composition comprising a compound configured to form internal 11 bonds, and an inorganic material, wherein the composition is defined by a first surface opposing a second surface and a first thickness measured from the first surface to the second surface of the composition.

Example 2. The composition of Example 1, wherein the internal 11 bonds comprise π-π stacking.

Example 3. The composition of Example 1 or 2, wherein the compound is a charge transport material.

Example 4. The composition of any preceding Examples, wherein the compound comprises an organic triphenylamine-based molecule.

Example 5. The composition of Example 4, wherein the organic triphenylamine-based molecule comprises Spiro-OMeTAD.

Example 6. The composition of any preceding Examples, wherein the inorganic material is at least partially insulating.

Example 7. The composition of any preceding Examples, wherein the inorganic material comprises a metal oxide, a metalloid oxide, a metal hydroxide, a metal oxyhydroxide, a ceramic material, or any combination thereof.

Example 8. The composition of any preceding Examples, wherein a first portion of the inorganic material is dispersed within the first surface and within at least a portion of the first thickness of the composition.

Example 9. The composition of Example 8, wherein the first portion of the inorganic material is disposed within a second thickness measured from the first surface, wherein the second thickness is smaller than the first thickness.

Example 10. The composition of Example 9, wherein the second thickness is from about 20 nm to about 60 nm.

Example 11. The composition of any preceding Examples, wherein a second portion of the inorganic material is disposed on the first surface.

Example 12. The composition of any preceding Examples, wherein at least a portion of the inorganic material is present as one or more clusters.

Example 13. The composition of any preceding Examples, wherein the inorganic material comprises one or more of Al_{y}Oₓ, SiOₓ, HfOₓ, ZrOₓ, Ta_{y}Oₓ, Y_{y}Oₓ, Ir_{y}Oₓ, RuOₓ, WOₓ, Ni_{y}Oₓ, TiOx, InOₓ, NiOₓ, ZnOₓ, CuOₓ, V_{y}O_{z}, Al_{y}OₓH_{z}, SiOₓH_{z}, HfOₓH_{z}, ZrOₓH_{z}, Ta_{y}OₓH_{z}, Y_{y}OₓH_{z}, Ir_{y}OₓH_{z}, RuOₓH_{z}, WOₓH_{z}, Ni_{y}OₓH_{z}, TiOₓH_{z}, InOₓH_{z}, NiOₓH_{z}, ZnOₓH_{z}, CuOₓH_{z}, V_{y}O_{z}H_{z}, or a combination thereof.

Example 14. The composition of any preceding Examples, wherein the composition is substantially stable and does not degrade at a temperature from room temperature to 85° C.

Example 15. The composition of any preceding Examples, wherein the composition is substantially free of crystalline phase at a temperature of 60° C. to 85° C.

Example 16. The composition of any preceding Examples, wherein the inorganic material is a nanosheet, a nanoparticle, a nanowire, or any combination thereof.

Example 17. The composition of any preceding Examples, wherein the compound comprises Spiro-OMeTAD and the inorganic material comprises TiO₂.

Example 18. The composition of any preceding Examples, wherein at least a portion of the π-π stacking is disrupted.

Example 19. The composition of any preceding Examples, wherein the composition is formed by a vapor phase infiltration (VPI).

Example 20. A device comprising at least one composition of any preceding Examples.

Example 21. The device of Example 20, wherein the device is a photovoltaic cell.

Example 22. A photovoltaic device comprising: a perovskite material layer; and a layer comprising a composition comprising a compound and an inorganic material, wherein the layer is defined by a first surface opposing a second surface and a first thickness measured from the first surface to the second surface; wherein the second surface overlays the perovskite material layer, wherein the compound comprises a Spiro-OMeTAD.

Example 23. A method of making the composition of any preceding Examples, the method comprises: exposing a layer of the compound to a vapor phase comprising a first precursor for a first predetermined time, thereby at least partially adsorbing at least a portion of the first precursor on a surface of the layer and/or at least partially infiltrating the layer of the compound with at least a portion of the first precursor to form a modified compound; and exposing the modified compound to a second precursor for a second predetermined time, thereby reacting the first precursor with the second precursor to form the inorganic material, thereby forming the composition comprising a first portion of the inorganic material dispersed within the layer of the compound and a second portion of the inorganic material at least partially disposed on the surface of the layer.

Example 24. The method of Example 23, wherein the first precursor comprises a metal salt, metal-organic, organometallic, or any combination thereof.

Example 25. The method of Example 23, wherein the second precursor is a water vapor, oxygen gas, ozone, hydrogen peroxide, or any combination thereof.

### REFERENCES

Song, Z.; McElvany, C. L.; Phillips, A. B.; Celik, I.; Krantz, P. W.; Watthage, S. C.; Liyanage, G. K.; Apul, D.; Heben, M. J. A Technoeconomic Analysis of Perovskite Solar Module Manufacturing with Low-Cost Materials and Techniques. Energy & Environmental Science 2017, 10 (6), 1297-1305. https://doi.org/10.1039/C7EE00757D.
Kojima, A.; Teshima, K.; Shirai, Y.; Miyasaka, T. Organometal Halide Perovskites as Visible-Light Sensitizers for Photovoltaic Cells. J Am Chem Soc 2009, 131 (17), 6050-6051. https://doi.org/10.1021/JA809598R/SUPPL_FILE/JA809598R_SI_001.PDF.
Yoo, J. J.; Seo, G.; Chua, M. R.; Park, T. G.; Lu, Y.; Rotermund, F.; Kim, Y. K.; Moon, C. S.; Jeon, N. J.; Correa-Baena, J. P.; Bulović, V.; Shin, S. S.; Bawendi, M. G.; Seo, J. Efficient Perovskite Solar Cells via Improved Carrier Management. Nature 2021 590:7847 2021, 590 (7847), 587-593. https://doi.org/10.1038/s41586-021-03285-w.
Min, H.; Lee, D. Y.; Kim, J.; Kim, G.; Lee, K. S.; Kim, J.; Paik, M. J.; Kim, Y. K.; Kim, K. S.; Kim, M. G.; Shin, T. J.; Il Seok, S. Perovskite Solar Cells with Atomically Coherent Interlayers on SnO2 Electrodes. Nature 2021 598:7881 2021, 598 (7881), 444-450. https://doi.org/10.1038/s41586-021-03964-8.
Song, Z.; Abate, A.; Watthage, S. C.; Liyanage, G. K.; Phillips, A. B.; Steiner, U.; Graetzel, M.; Heben, M. J. Perovskite Solar Cell Stability in Humid Air: Partially Reversible Phase Transitions in the PbI2-CH3NH3I—H2O System. Advanced Energy Materials 2016. https://doi.org/10.1002/aenm.201600846.
Turren-Cruz, S. H.; Hagfeldt, A.; Saliba, M. Methylammonium-Free, High-Performance, and Stable Perovskite Solar Cells on a Planar Architecture. Science (1979) 2018, 362 (6413), 449-453. https://doi.org/10.1126/SCIENCE.AAT3583/SUPPL_FILE/AAT3583-TURREN-CRUZ-SM.PDF.
An, Y.; Andrea, C.; Perini, R.; Hidalgo, J.; Castro-Mé Ndez, A. S.-F.; Vagott, J. N.; Li, R.; Saidi, W. A.; Wang, S.; Li, X.; Correa-Baena, J.-P. P.; Perini, C. A. R.; Hidalgo, J.; Castro-Méndez, A. F.; Vagott, J. N.; Li, R.; Saidi, W. A.; Wang, S.; Li, X.; Correa-Baena, J.-P. P. Identifying High-Performance and Durable Methylammonium-Free Lead Halide Perovskites via High-Throughput Synthesis and Characterization. Energy & Environmental Science 2021, 14 (12), 6638-6654. https://doi.org/10.1039/D1EE02691G.
Jones, D. (Mac); An, Y.; Hidalgo, J.; Evans, C.; Vagott, J. N.; Correa-Baena, J.-P. P. Polymers and Interfacial Modifiers for Durable Perovskite Solar Cells: A Review. Journal of Materials Chemistry C 2021, 9 (37), 12509-12522. https://doi.org/10.1039/D1TC01243F.
Leijtens, T.; Eperon, G. E.; Pathak, S.; Abate, A.; Lee, M. M.; Snaith, H. J. Overcoming Ultraviolet Light Instability of Sensitized TiO2 with Meso-Superstructured Organometal Tri-Halide Perovskite Solar Cells. Nature Communications 2013. https://doi.org/10.1038/ncomms3885.
Meng, L.; You, J.; Yang, Y. Addressing the Stability Issue of Perovskite Solar Cells for Commercial Applications. Nature Communications 2018 9:1 2018, 9 (1), 1-4. https://doi.org/10.1038/s41467-018-07255-1.
Wang, R.; Mujahid, M.; Duan, Y.; Wang, Z. K.; Xue, J.; Yang, Y. A Review of Perovskites Solar Cell Stability. Advanced Functional Materials 2019, 29 (47), 1808843. https://doi.org/10.1002/ADFM.201808843.
Barranco, A.; Lopez-Santos, M. C.; Idigoras, J.; Aparicio, F. J.; Obrero-Perez, J.; Lopez-Flores, V.; Contreras-Bernal, L.; Rico, V.; Ferrer, J.; Espinos, J. P.; Borras, A.; Anta, J. A.; Sanchez-Valencia, J. R. Enhanced Stability of Perovskite Solar Cells Incorporating Dopant-Free Crystalline Spiro-OMeTAD Layers by Vacuum Sublimation. Advanced Energy Materials 2020, 10 (2), 1901524. https://doi.org/10.1002/AENM.201901524.
Kasparavicius, E.; Franckevicius, M.; Malinauskiene, V.; Genevičius, K.; Getautis, V.; Malinauskas, T. Oxidized Spiro-OMeTAD: Investigation of Stability in Contact with Various Perovskite Compositions. ACS Applied Energy Materials 2021, 4 (12), 13696-13705. https://doi.org/10.1021/ACSAEM.1C02375/ASSET/IMAGES/LARGE/AE1C02375_0007.JPEG
Wang, S.; Yuan, W.; Meng, Y. S. Spectrum-Dependent Spiro-OMeTAD Oxidization Mechanism in Perovskite Solar Cells. ACS Applied Materials and Interfaces 2015, 7 (44), 24791-24798. https://doi.org/10.1021/ACSAMI.5B07703/ASSET/IMAGES/AM-2015-07703F_M010.GIF.
Domanski, K.; Correa-Baena, J. P.; Mine, N.; Nazeeruddin, M. K.; Abate, A.; Saliba, M.; Tress, W.; Hagfeldt, A.; Grätzel, M. Not All That Glitters Is Gold: Metal-Migration-Induced Degradation in Perovskite Solar Cells. ACS Nano 2016, 10 (6), 6306-6314. https://doi.org/10.1021/ACSNANO.6B02613/ASSET/IMAGES/LARGE/NN-2016-026139_0006.JPEG.
Domanski, K.; Correa-Baena, J. P.; Mine, N.; Nazeeruddin, M. K.; Abate, A.; Saliba, M.; Tress, W.; Hagfeldt, A.; Grätzel, M. Not All That Glitters Is Gold: Metal-Migration-Induced Degradation in Perovskite Solar Cells. ACS Nano 2016, 10 (6), 6306-6314. https://doi.org/10.1021/ACSNANO.6B02613/ASSET/IMAGES/LARGE/NN-2016-026139_0006.JPEG.
Meng, Q.; Chen, Y.; Xiao, Y. Y.; Sun, J.; Zhang, X.; Han, C. B.; Gao, H.; Zhang, Y.; Yan, H. Effect of Temperature on the Performance of Perovskite Solar Cells. Journal of Materials Science: Materials in Electronics 2021, 32 (10), 12784-12792. https://doi.org/10.1007/S10854-020-03029-Y/FIGURES/6.
Sheikh, A. D.; Munir, R.; Haque, M. A.; Bera, A.; Hu, W.; Shaikh, P.; Amassian, A.; Wu, T. Effects of High Temperature and Thermal Cycling on the Performance of Perovskite Solar Cells: Acceleration of Charge Recombination and Deterioration of Charge Extraction. ACS Applied Materials and Interfaces 2017, 9 (40), 35018-35029. https://doi.org/10.1021/ACSAMI.7B11250/ASSET/IMAGES/LARGE/AM-2017-11250N_0008.JPEG.
Tumen-Ulzii, G.; Qin, C.; Matsushima, T.; Leyden, M. R.; Balijipalli, U.; Klotz, D.; Adachi, C. Understanding the Degradation of Spiro-OMeTAD-Based Perovskite Solar Cells at High Temperature. Solar RRL 2020, 4 (10), 2000305. https://doi.org/10.1002/SOLR.202000305.
Sheikh, A. D.; Munir, R.; Haque, M. A.; Bera, A.; Hu, W.; Shaikh, P.; Amassian, A.; Wu, T. Effects of High Temperature and Thermal Cycling on the Performance of Perovskite Solar Cells: Acceleration of Charge Recombination and Deterioration of Charge Extraction. ACS Applied Materials and Interfaces 2017, 9 (40), 35018-35029. https://doi.org/10.1021/ACSAMI.7B11250/ASSET/IMAGES/LARGE/AM-2017-11250N_0008.JPEG.
Saliba, M.; Orlandi, S.; Matsui, T.; Aghazada, S.; Cavazzini, M.; Correa-Baena, J.-P.; Gao, P.; Scopelliti, R.; Mosconi, E.; Dahmen, K.-H.; De Angelis, F.; Abate, A.; Hagfeldt, A.; Pozzi, G.; Graetzel, M.; Nazeeruddin, M. K. A Molecularly Engineered Hole-Transporting Material for Efficient Perovskite Solar Cells. Nature Energy 2016, 1 (2), 1-7. https://doi.org/10.1038/nenergy.2015.17.
Matsui, T.; Petrikyte, I.; Malinauskas, T.; Domanski, K.; Daskeviciene, M.; Steponaitis, M.; Gratia, P.; Tress, W.; Correa-Baena, J. P.; Abate, A.; Hagfeldt, A.; Gratzel, M.; Nazeeruddin, M. K.; Getautis, V.; Saliba, M. Additive-Free Transparent Triarylamine-Based Polymeric Hole-Transport Materials for Stable Perovskite Solar Cells. ChemSusChem 2016, 9 (18), 2567-2571. https://doi.org/10.1002/cssc.201600762.
Seo, S.; Shin, S.; Kim, E.; Jeong, S.; Park, N. G.; Shin, H. Amorphous TiO2 Coatings Stabilize Perovskite Solar Cells. ACS Energy Letters 2021, 6 (9), 3332-3341. https://doi.org/10.1021/ACSENERGYLETT.1C01446/ASSET/IMAGES/LARGE/N Z1C01446_0005.JPEG.
Deng, K.; Li, L.; Deng, K.; Li, L. Advances in the Application of Atomic Layer Deposition for Organometal Halide Perovskite Solar Cells. Advanced Materials Interfaces 2016, 3 (21), 1600505. https://doi.org/10.1002/ADMI.201600505.
Seo, S.; Jeong, S.; Park, H.; Shin, H.; Park, N. G. Atomic Layer Deposition for Efficient and Stable Perovskite Solar Cells. Chemical Communications 2019, 55 (17), 2403-2416. https://doi.org/10.1039/C8CC09578G.
Choi, E. Y.; Kim, J.; Lim, S.; Han, E.; Ho-Baillie, A. W. Y.; Park, N. Enhancing Stability for Organic-Inorganic Perovskite Solar Cells by Atomic Layer Deposited Al₂O₃ Encapsulation. Solar Energy Materials and Solar Cells 2018, 188, 37-45. https://doi.org/10.1016/J.SOLMAT.2018.08.016.
Rajbhandari, P. P.; Dhakal, T. P. Low Temperature ALD Growth Optimization of ZnO, TiO2, and Al2O3 to Be Used as a Buffer Layer in Perovskite Solar Cells. Journal of Vacuum Science & Technology A: Vacuum, Surfaces, and Films 2020, 38 (3), 032406. https://doi.org/10.1116/1.5139247.
Zardetto, V.; Williams, B. L.; Perrotta, A.; Di Giacomo, F.; Verheijen, M. A.; Andriessen, R.; Kessels, W. M. M.; Creatore, M. Atomic Layer Deposition for Perovskite Solar Cells: Research Status, Opportunities and Challenges. Sustainable Energy & Fuels 2017, 1 (1), 30-55. https://doi.org/10.1039/C6SE00076B.
Brinkmann, K. O.; Gahlmann, T.; Riedl, T. Atomic Layer Deposition of Functional Layers in Planar Perovskite Solar Cells. Solar RRL 2020, 4 (1), 1900332. https://doi.org/10.1002/SOLR.201900332.
Correa Baena, J. P.; Steier, L.; Tress, W.; Saliba, M.; Neutzner, S.; Matsui, T.; Giordano, F.; Jacobsson, T. J.; Srimath Kandada, A. R.; Zakeeruddin, S. M.; Petrozza, A.; Abate, A.; Nazeeruddin, M. K.; Gratzel, M.; Hagfeldt, A. Highly Efficient Planar Perovskite Solar Cells through Band Alignment Engineering. Energy and Environmental Science 2015, 8 (10), 2928-2934. https://doi.org/10.1039/c5ee02608c.
Waldman, R. Z.; Mandia, D. J.; Yanguas-Gil, A.; Martinson, A. B. F.; Elam, J. W.; Darling, S. B. The Chemical Physics of Sequential Infiltration Synthesis-A Thermodynamic and Kinetic Perspective. The Journal of Chemical Physics 2019, 151 (19), 190901. https://doi.org/10.1063/1.5128108.
Leng, C. Z.; Losego, M. D. Vapor Phase Infiltration (VPI) for Transforming Polymers into Organic-Inorganic Hybrid Materials: A Critical Review of Current Progress and Future Challenges. Materials Horizons 2017, 4 (5), 747-771. https://doi.org/10.1039/C7MH00196G.
Obuchovsky, S.; Frankenstein, H.; Vinokur, J.; Hailey, A. K.; Loo, Y. L.; Frey, G. L. Mechanism of Metal Oxide Deposition from Atomic Layer Deposition inside Nonreactive Polymer Matrices: Effects of Polymer Crystallinity and Temperature. Chemistry of Materials 2016, 28 (8), 2668-2676. https://doi.org/10.1021/ACS.CHEMMATER.6B00159/ASSET/IMAGES/LARGE/C M-2016-00159N_0008.JPEG.
Sinha, A.; Hess, D. W.; Henderson, C. L. Transport Behavior of Atomic Layer Deposition Precursors through Polymer Masking Layers: Influence on Area Selective Atomic Layer Deposition. Journal of Vacuum Science & Technology B: Microelectronics and Nanometer Structures Processing, Measurement, and Phenomena 2007, 25 (5), 1721. https://doi.org/10.1116/1.2782546.
Sinha, A.; Hess, D. W.; Henderson, C. L. Area Selective Atomic Layer Deposition of Titanium Dioxide: Effect of Precursor Chemistry. Journal of Vacuum Science & Technology B: Microelectronics and Nanometer Structures Processing, Measurement, and Phenomena 2006, 24 (6), 2523. https://doi.org/10.1116/1.2359728.
Gregory, S. A.; Li, Y.; Monroe, T. D.; Li, J.; Yee, S. K.; Losego, M. D. Vapor Phase Infiltration Doping of the Semiconducting Polymer Poly(Aniline) with TiCl4+H2O: Mechanisms, Reaction Kinetics, and Electrical and Optical Properties. ACS Applied Polymer Materials 2021, 3 (2), 720-729. https://doi.org/10.1021/ACSAPM.0C01014/SUPPL_FILE/AP0C01014_SI_001.PD F.
Lin, G.; Zhao, M.-Q.; Jia, M.; -, al; Maeng, W. J.; Kim -, H.; Foroughi-Abari, A.; Cadien, K. C.; Niemela, J.-P.; Marin, G.; Karppinen, M. Titanium Dioxide Thin Films by Atomic Layer Deposition: A Review. Semiconductor Science and Technology 2017, 32 (9), 093005. https://doi.org/10.1088/1361-6641/AA78CE.
Sinha, A.; Hess, D. W.; Henderson, C. L. Transport Behavior of Atomic Layer Deposition Precursors through Polymer Masking Layers: Influence on Area Selective Atomic Layer Deposition. Journal of Vacuum Science & Technology B: Microelectronics and Nanometer Structures Processing, Measurement, and Phenomena 2007, 25 (5), 1721. https://doi.org/10.1116/1.2782546.
Ye, X.; Kestell, J.; Kisslinger, K.; Liu, M.; Grubbs, R. B.; Boscoboinik, J. A.; Nam, C. Y. Effects of Residual Solvent Molecules Facilitating the Infiltration Synthesis of ZnO in a Nonreactive Polymer. Chemistry of Materials 2017, 29 (10), 4535-4545. https://doi.org/10.1021/ACS.CHEMMATER.7B01222/ASSET/IMAGES/LARGE/C M-2017-01222H_0005.JPEG.
Gunn, F.; Ghosh, P.; Maciejczyk, M.; Cameron, J.; Nordlund, D.; Krishnamurthy, S.; Tuttle, T.; Skabara, P.; Robertson, N.; Ivaturi, A. Understanding the Dopant Induced Effects on SFX-MeOTAD for Perovskite Solar Cells: A Spectroscopic and Computational Investigation. Journal of Materials Chemistry C 2021, 9 (45), 16226-16239. https://doi.org/10.1039/DiTC04172J.
Zhang, Y.; Chen, Q.; Yang, H. S.; Kim, D.; Shin, I.; Lee, B. R.; Kim, J. H.; Moon, D. K.; Kim, K. H.; Park, S. H. Water-Repellent Perovskites Induced by a Blend of Organic Halide Salts for Efficient and Stable Solar Cells. ACS Applied Materials and Interfaces 2021, 13 (28), 33172-33181. https://doi.org/10.1021/ACSAMI.1C09093/ASSET/IMAGES/LARGE/AM1C09093_0008.JPEG
Perini, C. A. R.; Doherty, T. A. S.; Stranks, S. D.; Correa-Baena, J. P.; Hoye, R. L. Z. Pressing Challenges in Halide Perovskite Photovoltaics—from the Atomic to Module Level. Joule 2021, 5 (5), 1024-1030. https://doi.org/10.1016/J.JOULE.2021.03.011.
Parida, B.; Singh, A.; Oh, M.; Jeon, M.; Kang, J. W.; Kim, H. Effect of Compact TiO2 Layer on Structural, Optical, and Performance Characteristics of Mesoporous Perovskite Solar Cells. Materials Today Communications 2019, 18, 176-183. https://doi.org/10.1016/J.MTCOMM.2018.12.007.
Hu, H.; Dong, B.; Hu, H.; Chen, F.; Kong, M.; Zhang, Q.; Luo, T.; Zhao, L.; Guo, Z.; Li, J.; Xu, Z.; Wang, S.; Eder, D.; Wan, L. Atomic Layer Deposition of TiO2 for a High-Efficiency Hole-Blocking Layer in Hole-Conductor-Free Perovskite Solar Cells Processed in Ambient Air. ACS Applied Materials and Interfaces 2016, 8 (28), 17999-18007. https://doi.org/10.1021/ACSAMI.6B02701/ASSET/IMAGES/LARGE/AM-2016-02701U_0011.JPEG.
Jena, A. K.; Numata, Y.; Ikegami, M.; Miyasaka, T. Role of Spiro-OMeTAD in Performance Deterioration of Perovskite Solar Cells at High Temperature and Reuse of the Perovskite Films to Avoid Pb-Waste. Journal of Materials Chemistry A 2018, 6 (5), 2219-2230. https://doi.org/10.1039/C7TA07674F.
Tumen-Ulzii, G.; Qin, C.; Matsushima, T.; Leyden, M. R.; Balijipalli, U.; Klotz, D.; Adachi, C. Understanding the Degradation of Spiro-OMeTAD-Based Perovskite Solar Cells at High Temperature. Solar RRL 2020, 4 (10), 2000305. https://doi.org/10.1002/SOLR.202000305.
Shi, D.; Qin, X.; Li, Y.; He, Y.; Zhong, C.; Pan, J.; Dong, H.; Xu, W.; Li, T.; Hu, W.; Brédas, J. L.; Bakr, O. M. Spiro-OMeTAD Single Crystals: Remarkably Enhanced Charge-Carrier Transport via Mesoscale Ordering. Science Advances 2016, 2 (4). https://doi.org/10.1126/SCIADV.1501491/SUPPL_FILE/1501491_SM.PDF.

1. A composition comprising a compound configured to form internal π bonds, and an inorganic material, wherein the composition is defined by a first surface opposing a second surface and a first thickness measured from the first surface to the second surface of the composition.

2. The composition of claim 1, wherein the internal π bonds comprise π-π stacking.

3. The composition of claim 1, wherein the compound is a charge transport material.

4. The composition of claim 1, wherein the compound comprises an organic triphenylamine-based molecule.

5. The composition of claim 4, wherein the organic triphenylamine-based molecule comprises Spiro-OMeTAD.

6. The composition of claim 1, wherein the inorganic material is at least partially insulating.

7. The composition of claim 1, wherein the inorganic material comprises a metal oxide, a metalloid oxide, a metal hydroxide, a metal oxyhydroxide, a ceramic material, or any combination thereof.

8. The composition of claim 1, wherein a first portion of the inorganic material is dispersed within the first surface and within at least a portion of the first thickness of the composition.

9. The composition of claim 8, wherein the first portion of the inorganic material is disposed within a second thickness measured from the first surface, wherein the second thickness is smaller than the first thickness.

10. The composition of claim 9, wherein the second thickness is from about 20 nm to about 60 nm.

11. The composition of claim 1, wherein a second portion of the inorganic material is disposed on the first surface.

12. The composition of claim 1, wherein at least a portion of the inorganic material is present as one or more clusters.

13. The composition of claim 1, wherein the inorganic material comprises one or more of Al_{y}Oₓ, SiOₓ, HfOₓ, ZrOₓ, Ta_{y}Oₓ, Y_{y}Oₓ, Ir_{y}Oₓ, RuOₓ, WOₓ, Ni_{y}Oₓ, TiOₓ, InOₓ, NiOₓ, ZnOₓ, CuOₓ, V_{y}O_{z}, Al_{y}OₓH_{z}, SiOₓH_{z}, HfOₓH_{z}, ZrOₓH_{z}, Ta_{y}OₓH_{z}, Y_{y}OₓH_{z}, Ir_{y}OₓH_{z}, RuOₓH_{z}, WOₓH_{z}, Ni_{y}OₓH_{z}, TiOₓH_{z}, InOₓH_{z}, NiOₓH_{z}, ZnOₓH_{z}, CuOₓH_{z}, V_{y}O_{z}H_{z}, or a combination thereof.

14. The composition of claim 1, wherein the composition is substantially stable and does not degrade at a temperature from room temperature to 85° C.

15. The composition of claim 1, wherein the composition is substantially free of crystalline phase at a temperature of 60° C. to 85° C.

16. The composition of claim 1, wherein the inorganic material is a nanosheet, a nanoparticle, a nanowire, or any combination thereof.

17. The composition of claim 1, wherein the compound comprises Spiro-OMeTAD and the inorganic material comprises TiO₂.

18. The composition of claim 2, wherein at least a portion of the π-π stacking is disrupted.

19. The composition of claim 1, wherein the composition is formed by a vapor phase infiltration (VPI).

20. A device comprising at least one composition of claim 1.

21. The device of claim 20, wherein the device is a photovoltaic cell.

22. A photovoltaic device comprising:
a perovskite material layer; and
a layer comprising a composition comprising a compound and an inorganic material, wherein the layer is defined by a first surface opposing a second surface and a first thickness measured from the first surface to the second surface; wherein the second surface overlays the perovskite material layer,
wherein the compound comprises a Spiro-OMeTAD.

23. A method of making the composition of claim 1, the method comprises:
exposing a layer of the compound to a vapor phase comprising a first precursor for a first predetermined time, thereby at least partially adsorbing at least a portion of the first precursor on a surface of the layer and/or at least partially infiltrating the layer of the compound with at least a portion of the first precursor to form a modified compound; and
exposing the modified compound to a second precursor for a second predetermined time, thereby reacting the first precursor with the second precursor to form the inorganic material, thereby forming the composition comprising a first portion of the inorganic material dispersed within the layer of the compound and a second portion of the inorganic material at least partially disposed on the surface of the layer.

24. The method of claim 23, wherein the first precursor comprises a metal salt, metal-organic, organometallic, or any combination thereof.

25. The method of claim 23, wherein the second precursor is a water vapor, oxygen gas, ozone, hydrogen peroxide, or any combination thereof.

26. (canceled)
